(19) United States
(12) Patent Application Publication
(10) Pub. No.: US 2023/0144705 A1
(43) Pub. Date: May 11, 2023

(54) SYSTEMS AND METHODS FOR MATERIAL ILLUMINATION

(71) Applicant: Smartex Europe, Unipessoal LDA, Porto (PT)

(72) Inventors: Gilberto MARTINS LOUREIRO, Porto (PT); Antonio ROCHA, Porto (PT); Paulo RIBEIRO, Porto (PT); Márcio QUINTELA, Porto (PT)

(21) Appl. No.: 18/054,052

(22) Filed: Nov. 9, 2022

Related U.S. Application Data
(63) Continuation of application No. PCT/IB2021/054020, filed on May 11, 2021.

(30) Foreign Application Priority Data
May 12, 2020 (PT) PCT/PT2020/050020

(51) Int. Cl. H01L 27/15; G02B 27/30; F21K 9/237; F21K 9/60

(52) U.S. Cl. CPC H01L 27/156; G02B 27/30; F21K 9/237; F21K 9/60; F21W 2131/403

(57) ABSTRACT

Illumination modules (530) are described for use during manufacturing processes and subsequent material processing steps. The illumination modules (530) may assist with implementing methods for performing quality assurance or defect detection while material (510) is being manufactured or processed. Methods are also described for utilizing an illumination module to facilitate the detection of material properties or conformations as a part of quality assurance or defect detection algorithms.

### CROSS-REFERENCE

This application is a Continuation Application of International Application No. PCT/IB2021/054020 filed on May 11, 2021, which claims priority to International Application No. PCT/PT2020/050020 filed on May 12, 2020, each of which is incorporated herein by reference in its entirety for all purposes.

### BACKGROUND

Some materials and products may be produced by high-volume manufacturing processes. Such materials and products may include textiles such as natural or synthetic fabrics, structural materials such as sheet metals, piping, and wood products, paper products and other materials such as ceramics, composites, and plastics.

Manufactured products may be produced via specialized machinery that produce such products on a continuous or batch-wise basis. For example, textiles may be produced on knitting or weaving machines that produce and/or process a continuous sheet of knitted fabric. Manufactured products may be produced in a range of dimensions including varying lengths, widths, or thicknesses. Manufacturing equipment and machinery may include process sensing and control equipment.

### SUMMARY

Recognized herein is a need to provide illumination sources for material manufacturing quality assurance and defect detection systems. Such system may utilize one or more types of light, such as visible, ultraviolet (UV), or infrared (IR) light, to determine material properties or abnormalities present in the product during a manufacturing process. It may be advantageous to have illumination modules capable of providing light at multiple wavelengths to enable multiple modes of detection. It may be further advantageous to have illumination modules that are capable of providing light that has been collimated or otherwise ordered, and can be directed at a material surface over a broad range of incidence angles and light intensities.

Described herein are illumination modules that may be incorporated in quality assurance or defect detection systems. The illumination modules comprise one or more light-emitting elements coupled to a mechanical support structure with accompanying electrical connections, and optionally integrated optical elements that order or direct the emitted light. In some embodiments, the light-emitting elements may include LED chips that are capable of providing light at multiple wavelengths or over a range of wavelengths. In some embodiments, the light-emitting elements are coupled with collimating lenses to provide light with a substantially uniform direction of emission from the illumination module. The illumination modules may be integrated with detectors and computer systems to provide high-sensitivity quality assurance or defect detection systems.

In an aspect, provided herein is an illumination system comprising one or more light sources configured to emit light, and an optical element in optical communication with the one or more light sources, wherein the optical element is configured to direct the light onto a material sheet to provide illumination along one or more axes of the material sheet, which one or more axes are associated with one or more directions in which the material sheet is produced, and wherein the illumination is useable to illuminate a target region of the material sheet to enable detection of one or more defects or to ensure quality control during a production or a processing of the material sheet.

In some embodiments, the optical element comprises one or more light organizing elements. In some embodiments, the one or more light organizing elements comprises a direction-altering element or an intensity-altering element. In some embodiments, the direction-altering element is selected from the group consisting of a collimating lens, a focusing lens, a focusing mirror, a defocusing lens, a defocusing mirror, a planar mirror, a parabolic mirror, a polygon rotating mirror, and a polarizing lens. In some embodiments, the intensity-altering element is selected from the group consisting of a filtering lens, a beam splitter, a dichroic mirror, an iris, an aperture, a semi-transparent material, an attenuator, a patterned attenuator, and an opening or an aperture.

In some embodiments, the one or more light sources comprises one or more light emitting diodes (LEDs). In some embodiments, the illumination system comprises a chip comprising one or more LEDs. In some embodiments, the one or more LEDs comprises an array of LEDs that are spaced apart along a longitudinal axis.

In some embodiments, the optical element is operatively coupled to the chip. In some embodiments, the optical element is molded over the chip.

In some embodiments, the one or more light sources are configured to emit light selected from the group consisting of visible light, infrared light, and ultraviolet light. In some embodiments, the light comprises one or more beams having a wavelength from about 10 nanometers to about 1200 nanometers.

In some embodiments, the one or more axes comprises a predefined axis that is in a vertical direction along which the material sheet is produced.

In some embodiments, an optical axis of the light is transverse to the predefined axis of material sheet.

In some embodiments, the collimating lens has a substantially semi-circular shape or a hemispherical shape. In some embodiments, the collimating lens has a radius of at least about five millimeters.

In some embodiments, the optical element is spaced apart from the one or more light sources by a gap. In some embodiments, the gap is at least one millimeter. In some embodiments, the optical element comprises a transparent plastic, a translucent plastic, a transparent glass, a translucent glass, a reflective metal, or a reflective coating.

In some embodiments, the illumination unit is configured to direct the light at one or more angles relative to a plane defined by the target region. In some embodiments, the one or more angles ranges from about 1 degree to about 360 degrees.

In some embodiments, the illumination is configured to produce substantially uniform brightness along the one or more axes of the material sheet.

In another aspect, the present disclosure provides a method comprising: providing an illumination system comprising (1) one or more light sources that emit light and (2) an optical element in optical communication with the one or more light sources, using the optical element to direct the light onto a material sheet to provide illumination along one or more axes of the material sheet, which one or more axes are associated with one or more directions in which the material sheet is produced, and using the illumination to illuminate a target region of the material sheet, for enabling detection of a material quality or one or more defects or ensuring quality control during a production or a processing of the material sheet.

In some embodiments, the material sheet is a textile. In some embodiments, the material sheet is a metal or metal alloy. In some embodiments, the material sheet is paper. In some embodiments, the material sheet is a plastic.

In some embodiments, the illumination comprises a collimated beam or a quasi-collimated beam.

In some embodiments, the illumination comprises low angle light. In some embodiments, the illumination is useable to generate one or more shadows in the target region, which shadows are useable to enable the detection of the one or more defects or to ensure quality control during the production or the processing of the material sheet.

In another aspect, the present disclosure provides an illumination system comprising: one or more light sources configured to emit light; and an optical element in optical communication with the one or more light sources and a material sheet, wherein the optical element is configured to direct the light onto the material sheet to provide illumination along one or more axes of the material sheet, which one or more axes are associated with one or more directions in which the material sheet is produced, and wherein the illumination is useable to illuminate a target region of the material sheet to enable detection of one or more defects or ensure quality control during a production or a processing of the material sheet.

In some embodiments, the optical element comprises one or more light organizing elements. In some embodiments, the one or more light organizing elements comprises a direction-altering element or an intensity-altering element. In some embodiments, the direction-altering element is selected from the group consisting of a collimating lens, a focusing lens, a focusing mirror, a defocusing lens, a defocusing mirror, a planar mirror, a parabolic mirror, a polygon rotating mirror, and a polarizing lens. In some embodiments, the intensity-altering element is selected from the group consisting of a filtering lens, a beam splitter, a dichroic mirror, an iris, an aperture, a semi-transparent material, an attenuator, a patterned attenuator, and an opening.

In some embodiments, the one or more light sources comprises one or more light emitting diodes (LEDs). In some embodiments, the system may comprise a chip comprising the one or more LEDs. In some embodiments, the one or more LEDs comprises an array of LEDs that are spaced apart along a longitudinal axis. In some embodiments, the optical element is operatively coupled to the chip. In some embodiments, the optical element is molded over the chip. In some embodiments, the one or more light sources are configured to emit light selected from the group consisting of visible light, infrared light, and ultraviolet light. In some embodiments, the light comprises one or more beams having a wavelength from about 10 nanometers to about 1200 nanometers.

In some embodiments, the one or more axes comprises a predefined axis that is in a vertical direction along which the material sheet is produced. In some embodiments, an optical axis of the light is transverse to the predefined axis of material sheet.

In some embodiments, the collimating lens has a substantially semi-circular shape or a hemispherical shape. In some embodiments, the collimating lens has a radius of at least about five millimeters.

In some embodiments, the optical element is spaced apart from the one or more light sources by a gap. In some embodiments, the gap is at least one millimeter. In some embodiments, the optical element comprises a transparent plastic, a translucent plastic, a transparent glass, a translucent glass, a reflective metal, or a reflective coating.

In some embodiments, the illumination unit is configured to direct light at one or more angles relative to a plane defined by the target region. In some embodiments, the one or more angles ranges from about 1 degree to about 360 degrees. In some embodiments, the illumination is configured to produce substantially uniform brightness along the one or more axes of the material sheet.

In another aspect, the present disclosure provides a method comprising: providing an illumination system comprising (1) one or more light sources that emits light and (2) an optical element in optical communication with the one or more light sources; using the optical element to direct light onto a material sheet to provide illumination along one or more axes of the material sheet, which one or more axes are associated with one or more directions in which the material sheet is produced; and using the illumination to illuminate a target region of the material sheet, for enabling detection of a material quality or one or more defects or ensuring quality control during a production or a processing of the material sheet.

In some embodiments, the material sheet is a textile. In some embodiments, the material sheet is a metal or metal alloy. In some embodiments, the material sheet is paper. In some embodiments, the material sheet is a plastic.

In some embodiments, the illumination comprises a collimated beam or a quasi-collimated beam. In some embodiments, the illumination comprises low angle light. In some embodiments, the illumination is useable to generate one or more shadows in the target region, which shadows are useable to enable detection of one or more defects or to ensure quality control during a production or processing of the material sheet.

In some embodiments, the material sheet comprises a web, a fabric, a sheet, a textile, paper, a woven material, a non-woven material, a metal, a plastic, a composite, or a film. In some embodiments, the material sheet is provided in or fabricated or processed using a material fabrication and processing machine. In some embodiments, the material fabrication and processing machine comprises a knitting machine. In some embodiments, the knitting machine comprises a circular knitting machine, a warp knitting machine, or a flat knitting machine. In some embodiments, the material fabrication and processing machine comprises a weaving machine. In some embodiments, the material fabrication and processing machine comprises a roll-to-roll processing machine.

In another aspect, the present disclosure provides a defect detection and quality control system comprising an illumination system and one or more imaging units configured to capture one or more images or videos of the material sheet based on light that is transmitted from the one or more light sources and reflected from the material sheet.

In some embodiments, the system may further comprise an image processing unit configured to detect one or more defects on the material sheet or aid in quality control for the material sheet based on the one or more images or videos. In some embodiments, the system may further comprise a calibration unit configured to calibrate a position and/or an orientation of the one or more light sources to illuminate one or more inspection areas on the material sheet. In some embodiments, the calibration unit may be configured to adjust one or more operational parameters of the one or more light sources. In some embodiments, the one or more operational parameters comprise an intensity, a color, a brightness, a temperature, a wavelength, a frequency, a pulse width, a pulse frequency, or any other parameter that controls a transmission of light/electromagnetic waves or a physical characteristic of light/electromagnetic waves.

In some embodiments, the calibration unit may be configured to calibrate a position and/or an orientation of the one or more imaging units relative to the one or more light sources or relative to the material sheet. In some embodiments, the calibration unit may be configured to adjust one or more imaging parameters of the one or more imaging units. In some embodiments, the one or more imaging parameters may comprise an exposure time, a shutter speed, an aperture, a film speed, a field of view, an area of focus, a focus distance, a capture rate, or a capture time associated with the one or more imaging parameters.

In some embodiments, the calibration unit may be configured to adjust a position, an orientation, and/or an operation of the one or more imaging units or the one or more light sources, based on the one or more images or videos captured using the one or more imaging units. In some embodiments, the one or more imaging units are fixed relative to the material sheet. In some embodiments, the one or more imaging units are rotatable relative to the material sheet. In some embodiments, the one or more imaging units are provided inside of a fabrics tube of a material fabrication or processing machine that is fabricating or processing the material sheet. In some embodiments, the one or more imaging units are provided outside of a fabrics tube of a material fabrication or processing machine that is fabricating or processing the material sheet. In some embodiments, the one or more light sources are positioned and/or oriented to provide low angle illumination on the material sheet.

Another aspect of the present disclosure provides a non-transitory computer readable medium comprising machine executable code that, upon execution by one or more computer processors, implements any of the methods above or elsewhere herein.

Another aspect of the present disclosure provides a system comprising one or more computer processors and computer memory coupled thereto. The computer memory comprises machine executable code that, upon execution by the one or more computer processors, implements any of the methods above or elsewhere herein.

Additional aspects and advantages of the present disclosure will become readily apparent to those skilled in this art from the following detailed description, where only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “figure” and “FIG.” herein), of which:

FIG. 1 presents a schematic of a computer system, in accordance with some embodiments.

FIGS. 2A, 2B, and 2C show differing fabric surface topologies created by various possible weaving defects, in accordance with some embodiments.

FIG. 3A displays the expected light shadowing created by the surface topology of a defect-free surface.

FIG. 3B displays the expected light shadowing created by the surface topology of a surface with a defect, in accordance with some embodiments.

FIGS. 4A and 4B depict various types of fabric weaves and the resultant surface topologies created by the differing weaves, in accordance with some embodiments.

FIGS. 5A, 5B, and 5C show possible orientations of illumination modules with respect to a material sheet and a light sensor, in accordance with some embodiments.

FIGS. 6A and 6B depict the path of a light beam interacting with defect-free and defective surfaces, in accordance with some embodiments.

FIG. 7A shows a cross-sectional view of an illumination module projecting a light beam onto a material surface.

FIG. 7B shows a face-on view of the illumination area created on the material surface, in accordance with some embodiments.

FIGS. 8A, 8B, and 8C show various views of an exemplary illumination module device, in accordance with some embodiments.

FIG. 9 displays an image of a prototype illumination module featuring light emitting diode (LED) chips arranged in a linear configuration, in accordance with some embodiments.

FIG. 10 depicts a schematic view of a collimating lens and LED chip assembly, in accordance with some embodiments.

FIG. 11 shows the passage of light from a light source passing through a collimating lens, in accordance with some embodiments.

FIG. 12 depicts the light beam orientation of differing illumination module configurations relative to a material sheet, in accordance with some embodiments.

FIG. 13 illustrates a knitted fabric pattern with the resulting surface topologies created by the knitting pattern, in accordance with some embodiments.

FIGS. 14A, 14B, and 14C depict the interaction of light beams with surface defects or surface features on a metal surface, a ceramic surface, and a polymer surface, respectively, in accordance with some embodiments.

FIG. 15 illustrates various examples of an optical detection system for defect detection and quality control that comprises a fixed camera, in accordance with some embodiments.

FIG. 16 illustrates schematically illustrates various examples of an optical detection system for defect detection and quality control that comprises a movable or rotatable camera, in accordance with some embodiments.

FIG. 17 illustrates various inspection areas that may be monitored using an imaging system or an optical detection system for defect detection and quality control, in accordance with some embodiments.

FIG. 18 illustrates an example of an inspection system comprising one or more illumination modules and one or more cameras.

FIG. 19 illustrates various examples of possible inspection areas for a material or web that is fabricated or processed using a weaving machine, in accordance with some embodiments.

FIG. 20 illustrates various examples of possible inspection areas for a material or web that is fabricated or processed using a warp knitting machine.

FIG. 21 illustrates various examples of possible inspection areas for a material or web that is fabricated or processed using a flat knitting machine.

FIG. 22 illustrates various examples of possible inspection areas for a material or web that is fabricated or processed using any type of roll-to-roll processing machine.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

As used herein, the term “material” generally refers to a product of a manufacturing process that may be subsequently utilized in one or more other manufacturing processes. For example, a knitting machine may produce a fabric material, which may be subsequently used to produce garments or other textile products. In another example, a metallurgical process may produce an untreated sheet metal material that may be subsequently used to cut parts or be formed into piping products. The material may comprise one or more textiles, metals, papers, polymers, composites, and/or ceramics. The term(s) “material” and “material surface” as referred to herein may encompass and may be used interchangeably with the term(s) “web”, “fabric”, “sheet”, “textile”, “surface material”, “paper”, “woven material”, “non-woven material”, “metal”, “plastic”, “composite”, or “film”.

As used herein, the term “product” generally refers to a composition produced from one or more manufactured materials by subsequent processing of the manufactured materials. For example, a knitted fabric material may be dyed, cut and/or sewn to produce a final garment product. A product may be an intermediate product or a final product.

As used herein, the term “defect” generally refers to an abnormality on the surface or within the volume of a material or product. Defects may include non-uniformities, non-conformities, misalignments, flaws, damages, aberrations, and irregularities in the material or product. As used herein, the term “regular defect” generally refers to a defect that repeats with a known pattern such as temporal recurrence, spatial recurrence, or repeating or similar morphology (e.g., holes of the same shape or size). As used herein, an “irregular defect” generally refers to a defect with a non-patterned recurrence such as temporal randomness, spatial randomness, or differing or dissimilar morphology (e.g., holes of random shapes or sizes).

As used herein, the term “quality” generally refers to a desired, predetermined, qualitative or quantitative property (or properties) of a material or product. A quality may encompass a plurality of properties that collectively form a standard for a material. For example, a quality of a textile may refer to a weight, color, thread count, thickness of the textile, fabric uniformity, smoothness, yarn uniformity, yarn thickness, absence of contaminations, or a combination thereof. As used herein, the term “substandard quality” generally refers to a material or product that fails to meet at least one quality control standard or benchmark for a desired property. In some cases, a substandard material or product may fail to meet more than one quality control standard or benchmark.

As used herein, the term “quality control” generally refers to a method of comparing a manufactured material or product to an established quality control standard or benchmark. A quality control method may comprise measuring one or more observable properties or parameters (e.g., length, width, depth, thickness, diameter, circumference, shape, color, density, weight, strength, etc.) of a manufactured material or product. Quality control may comprise comparison of one or more parameters of a material or product to a known benchmark or monitoring of variance of one or more parameters during a manufacturing process. Quality control may be qualitative (e.g., pass/fail) or quantitative (e.g., statistical analysis of measured parameters). A manufacturing process may be considered to meet a quality control standard if the variance of at least one material or product parameter is within about ±1%, ±2%, ±3%, ±4%, ±5%, ±6%, ±7%, ±8%, ±9%, or about ±10% of a quality control standard or benchmark.

As used herein, the term “calibrate,” “calibrating,” or “calibration” generally refers to calibrating one or more imaging units to one or more target regions of a material sheet. The calibrating may include providing the imaging unit(s) in a predetermined spatial configuration relative to a material fabrication machine that is useable to form the material sheet. The calibrating may also include providing the one or more imaging units in a predetermined spatial configuration for imaging the one or more target regions, such that the imaging unit(s) are in focus on the target region(s), and with the target region(s) lying within a field of view of the imaging unit(s). As used herein, the term “target region(s)” may generally refer to one or more regions that are defined on a material sheet. The target region(s) may be of any predetermined shape, size, dimension, or orientation.

The term “real-time,” as used herein, generally refers to a simultaneous or substantially simultaneous occurrence of a first event or action with respect to occurrence of a second event or action. A real-time action or event may be performed within a response time of less than one or more of the following: ten seconds, five seconds, one second, tenth of a second, hundredth of a second, a millisecond, or less relative to at least another event or action. A real-time action may be performed by one or more computer processors.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

The terms “a,” “an,” and “the,” as used herein, generally refers to singular and plural references unless the context clearly dictates otherwise.

In an aspect, the present disclosure provides illumination systems for use in material inspection, quality assurance, defect detection systems, and optical metrology systems. The illumination systems may provide patterned or targeted illumination of moving or static material surfaces to generate, for example, flowing flat material illumination during the production or processing of the material. The illumination systems may direct light to the surface of a moving or static material, such as a material sheet, during a manufacturing process (e.g., roll-to-roll production of fabric materials). The illumination systems may direct light to the surface of a moving or static material, during a processing step that occurs after the initial manufacturing process (e.g., de-linting of fabric, gauge reduction of a metal sheet). The material sheet may be flat and have a textured surface. The material sheet may be flexible or stretchable. The material sheet may move in one or more directions (e.g. translated and/or rolled) during a manufacturing process. Detection of the interactions of light from the illumination module via one or more sensors may permit assessment of qualitative and/or quantitative metrics of material quality, or may permit the detection of defects in the material as it is being produced. In some cases, the illumination module may transmit more than one type of light (e.g., ultraviolet (UV), visible, infrared (IR), etc.). Illumination modules capable of outputting multiple or types of light may be utilized to assess a broader range of material qualities or defects to be measured.

Illumination modules of the present disclosure may comprise arrays of light sources configured to direct light to the surface of a material. In some cases, an illumination module may provide light that impinges upon the surface of a moving or non-static material such that the illumination area remains fixed while the material translates or otherwise moves through the illumination area. The array of light sources may include regular or repeated light sources of a particular wavelength or range of wavelengths. An illumination module may also comprise one or more integrated optical components that alter the characteristics of the light produced. In some cases, an illumination module may comprise one or more collimating lenses that are integrated with the visible sources to produce collimated beams of visible light. An illumination module may comprise the array of light sources mounted onto a single element, such as a printed circuit board, that provides mechanical support for the module as well as electrical connections. An illumination module may be connected to or integrated with a sensor system to create a combined system for material quality assurance or defect detection.

Illumination modules of the present disclosure may have a broad range of operating modes to permit enhanced material inspection, quality assurance or defect detection. Illumination modules may provide constant or variable light intensity. Illumination modules may provide directional control or shaping of the emitted light beams (e.g., collimated beams) or may offer dispersion of light beams. The illumination modules may produce differing types and/or wavelengths of light at differing times or may simultaneously emit more than one wavelength at a time depending upon the mode of quality assurance or defect detection used. Illumination modules may be static or may adjust positions and/or orientations relative to the surface of a material being produced. Illumination modules may be positioned and/or oriented relative to the surface of a material to permit a particular type of property determination or defect detection. For example, an illumination module may be placed such that its light beam is orthogonal to a material surface, or is directed at a low angle relative to the material surface. Exemplary ranges for the aforementioned angle are described elsewhere herein.

### Materials and Manufacturing Processes

The present disclosure provides illumination modules for quality control or identifying defects during the manufacturing and processing of materials and products. Such defects or substandard materials or products may arise during the primary manufacturing process (e.g., the knitting of a fabric, forging of metal sheets) or may subsequently arise during additional secondary downstream processing (e.g., ironing or de-linting of a fabric, gauge reduction of a metal sheet). The products of the present invention may be broadly considered to encompass any manufactured product, including primary materials such as fabrics, sheet metals, and sheet polymers, and secondary materials produced from the utilization of primary materials, such as clothing, piping, or plastic containers. Materials of the present disclosure may include sheet materials such as those produced in a continuous, roll-to-roll fashion (e.g., fabrics, paper).

The illumination modules of the present disclosure may be utilized in a manufacturing process for any conceivable solid material. Of interest are solid, continuum materials. Such materials are produced in form factors such as sheets, nets, webs, films, tubes, blocks, rods, and discs. Materials may include textiles, metals, papers, polymers, composites, and ceramics.

Textiles may include any product produced from the spinning of fibers into long strands. Textiles may include yarns as well as products produced from the weaving or knitting of fibers into continuous fabrics. Textiles may be produced from natural or synthetic fibers. Natural fibers may include cotton, silk, hemp, bast, jute, wool, bamboo, sisal, and flax. Synthetic fibers may include nylon, rayon, polyester, acrylic, spandex, glass fiber, dyneema, orlon, and Kevlar. Textiles may be produced from a combination of fiber types such as cotton and polyester. Textiles may include additional components such as plastics and adhesives (e.g., carpet). Produced textiles may undergo additional processing such as de-sizing, scouring, bleaching, mercerizing, singeing, raising, calendering, shrinking, dyeing and printing.

Metals may include any metal, metal oxide or alloy products. Metals may include steels such as carbon steels and stainless steels. Metals may include pure metals such as copper and aluminum. Metals may include common alloys such as bronze and brass. Metals may be manufactured or cast in forms such as sheets, rods, and foils. Metals may undergo additional processing such as rolling, annealing, quenching, hardening, pickling, cutting, and stamping.

Papers may include any product produced from plant pulp such as sheet paper and cardboard. Paper products may include other materials such as plastics, metals, dyes, inks, and adhesives. Paper may undergo additional processes before or after production such as bleaching, cutting, folding, and printing.

Polymers may include polymer materials such as thermoplastics, crystalline plastics, conductive polymers and bioplastics. Exemplary polymers may include polyethylene, polypropylene, polyamides, polycarbonates, polyesters, polystyrenes, polyurethanes, polyvinyl chlorides, acrylics, teflons, polyetheretherketones, polyimides, polylactic acids, and polysulfones. Polymers may include rubbers and elastic materials. Polymers may include copolymers or composites of multiple polymers. Polymeric materials may incorporate other materials such as paper, metal, dyes, inks, and minerals. Polymeric materials may undergo additional processes after manufacture such as molding, cutting, and dying. Plastic products may include food containers, sheets and wraps, housing materials and innumerable other consumer products.

Ceramics may include a broad range of crystalline, semi-crystalline, vitrified, or amorphous inorganic solids. Ceramic products may include earthenware, porcelain, brick and refractory materials. Ceramics may range from materials that are transparent in the visible spectrum, such as glass, to non-transparent materials in the visible spectrum, such as bricks. Ceramics may form composites with other materials such as metals and fibers. Ceramics may undergo processes such as molding, hardening, cutting, glazing, and painting during the manufacture of ceramic products.

Composites may include any material that comprises two or more other types of materials. Exemplary composites may include building materials such as particle board and concrete, as well as other structural materials such as metal-carbon fiber composites. Composite materials may undergo similar additional processing methods as their substituent components.

In some cases, the present disclosure provides illumination modules for material inspection, quality assurance or defect detection during textile manufacture or processing. In a particular example, the present disclosure provides illumination modules for circular knitting machines. Circular knitting machines may include any manufacturing equipment for the production of tubular fabrics. In other cases, illumination modules may be provided for other equipment for knitting or weaving non-tubular fabrics.

In some examples, a knitting machine may comprise numerous parts, such as creels, pulleys, belts, brushes, tension disks, yarn guides, positive feeds, feeder rings, disk drums, pattern wheels, feeders, needle tracks, needles, sinkers, sinker rings, cam boxes, cams, cylinders, rollers, splitters, cutters, and fans. A knitting machine may be a roll-to-roll device.

In other cases, the present disclosure provides illumination modules for other material manufacturing processes, as well as subsequent processing. Such processes may include the continuous or batch-wise production of other materials such as sheet metal, piping or tubing, ceramics, polymers and composites.

Illumination modules may be utilized for quality assurance or defect detection purposes in continuous, semi-continuous or batch production of materials, such as textiles, metals, ceramics, polymers, paper and composites. Illumination modules may be located during or after a primary material manufacturing process, or after a secondary process following the production of a material. For example, an optical detection system utilizing an illumination module may be utilized to monitor the knitting or weaving of a fabric, utilized to inspect fabric as it is produced from a knitting machine, or utilized to inspect the fabric during or after any subsequent processing, such as calendering or dyeing. Optical detection systems utilizing illumination modules may be utilized to monitor roll-to-roll processes for the production of flexible sheet materials such as fabrics and metal foils. Optical detection systems with illumination modules may be utilized to monitor the production of finished products such as garments, piping, or polymer containers.

Manufacturing equipment including optical detection systems may produce or process a material product at a particular rate. The production or processing rate may be characterized in terms of length per time, area per time, volume per time, weight per time, units of product per time, or any other conceivable measure of productivity. The production or processing rate may be an average value for processes in which the production rate varies with time. In some cases, the production or processing may be continuous and have minimal changes in production rate.

Optical detection systems utilizing illumination modules may be applied to processes with a particular rate of material productivity or throughput. For example, a material produced from a manufacturing device (e.g., fabric from a circular knitting machine) may be produced at a particular area per time. An optical detection system utilizing an illumination module may monitor equipment producing or processing material at a rate of at least about 0.1 square meter per minute (m²/min), 0.5 m²/min, 1 m²/min, 2 m²/min, 5 m²/min, 10 m²/min, or more than about 10 m²/min. An optical detection system utilizing an illumination module may monitor equipment producing or processing material at a rate of no more than about 10 m²/min, 5 m²/min, 2 m²/min, 1 m²/min, 0.5 m²/min, 0.1 m²/min, or less than about 0.1 m²/min. In another example, a material produced or processed from a manufacturing device (e.g., fabric from a circular knitting machine) may be produced at a particular weight per time. An optical detection system utilizing an illumination module may monitor equipment producing or processing material at a rate of at least about 1 kilogram per day (kg/day), 5 kg/day, 10 kg/day, 25 kg/day, 50 kg/day, 100 kg/day, 150 kg/day, 200 kg/day, 300 kg/day, 400 kg/day, 500 kg/day, 600 kg/day, 700 kg/day, 800 kg/day, 900 kg/day, 1000 kg/day, or more than about 1000 kg/day. An optical detection system utilizing and illumination module may monitor equipment producing or processing material at a rate of no more than about 1000 kg/day, 900 kg/day, 800 kg/day, 700 kg/day, 600 kg/day, 500 kg/day, 400 kg/day, 300 kg/day, 200 kg/day, 150 kg/day, 100 kg/day, 50 kg/day, 25 kg/day, 10 kg/day, 5 kg/day, 1 kg/day, or less than about 1 kg/day.

A material may be produced from a manufacturing device or processed at a particular length or width. An illumination module may have field of view that is intended to encompass a portion or the entirety of the materials' characteristic length or width. An illumination module may illuminate a material being produced or processed with a width of at least about 1 millimeter (mm), 5 mm, 1 centimeter (cm), 2 cm, 5 cm, 10 cm, 20 cm, 50 cm, 100 cm, 150 cm, 200 cm, or more than about 200 cm. An illumination module may illuminate a material being produced or processed with a width of no more than about 200 cm, 150 cm, 100 cm, 50 cm, 20 cm, 10 cm, 5 cm, 2 cm, 1 cm, 5 mm, 1 mm, or less than about 1 mm.

A material may be produced from a manufacturing device (e.g., a fabric from a circular knitting machine) or subsequently processed at a characteristic thickness. The thickness of the material may vary over the length or width of the material as it is produced. The material may have an average thickness of about 0.1 mm, 0.5 mm, 1 mm, 2 mm, 3 mm, 4 mm, 5 mm, 6 mm, 7 mm, 8 mm, 9 mm, 1 cm, 2 cm, 5 cm, 10 cm, or more than 10 cm. The material may have an average thickness of at least about 0.1 mm, 0.5 mm, 1 mm, 2 mm, 3 mm, 4 mm, 5 mm, 6 mm, 7 mm, 8 mm, 9 mm, 1 cm, 2 cm, 5 cm, 10 cm, or more than about 10 cm. The material may have an average thickness of no more than about 10 cm, 5 cm, 2 cm, 1 cm, 9 mm, 8 mm, 7 mm, 6 mm, 5 mm, 4 mm, 3 mm, 2 mm, 1 mm, 0.5 mm, 0.1 mm, or less than 0.1 mm.

A material may be produced from a manufacturing device (e.g., a fabric from a circular knitting machine) or processed on a processing device at a characteristic velocity. The velocity of the material may be measured at the exit from manufacturing device or at a location downstream of the manufacturing device. A material may be produced from a manufacturing device or processed at a velocity of about 0.01 meters per second (m/s), 0.1 m/s, 0.5 m/s, 1 m/s, 2 m/s, 3 m/s, 4 m/s, 5 m/s, 6 m/s, 7 m/s, 8 m/s, 9 m/s, 10 m/s, 15 m/s, 20 m/s, 25 m/s, 30 m/s, 35 m/s, 40 m/s, 45 m/s, 50 m/s, 60 m/s, 70 m/s, 80 m/s, 90 m/s, 100 m/s, or more than 100 m/s. A material may be produced from a manufacturing device or processed at a velocity of at least about 0.01 m/s, 0.1 m/s, 0.5 m/s, 1 m/s, 2 m/s, 3 m/s, 4 m/s, 5 m/s, 6 m/s, 7 m/s, 8 m/s, 9 m/s, 10 m/s, 15 m/s, 20 m/s, 25 m/s, 30 m/s, 35 m/s, 40 m/s, 45 m/s, 50 m/s, 60 m/s, 70 m/s, 80 m/s, 90 m/s, 100 m/s, or more than 100 m/s. A material may be produced from a manufacturing device or processed at a velocity of about 100 meters per second (m/s), 90 m/s, 80 m/s, 70 m/s, 60 m/s, 50 m/s, 45 m/s, 40 m/s, 35 m/s, 30 m/s, 25 m/s, 20 m/s, 15 m/s, 10 m/s, 9 m/s, 8 m/s, 7 m/s, 6 m/s, 5 m/s, 4 m/s, 3 m/s, 2 m/s, 1 m/s, 80 m/s, 0.1 m/s, 0.01 m/s, or less than 0.01 m/s.

Materials or products may be porous or non-porous. In some cases, the porosity of a material or product may be detectable by an imaging system. In other cases, the porosity of a material or product may not be detectable by an imaging system. The porosity of a material or product may be regular, patterned, or random. The porosity of a material or product may have a particular pore size distribution. The pore size distribution of porosity may be monomodal, bimodal, or polymodal. A porous material or product may be characterized by pores with an average size (e.g., length, width, depth, diameter) of about 10 nanometers (nm), 100 nm, 1 micrometer (μm), 10 μm, 100 μm, 250 μm, 500 μm, 1 mm, 2 mm, 3 mm, 4 mm, 5 mm, 6 mm, 7 mm, 8 mm, 9 mm, 10 mm, or more than 10 mm. A porous material or product may be characterized by pores with an average size of at least about 10 nm, 100 nm, 1 μm, 10 μm, 100 μm, 250 μm, 500 μm, 1 mm, 2 mm, 3 mm, 4 mm, 5 mm, 6 mm, 7 mm, 8 mm, 9 mm, 10 mm, or more than about 10 mm. A porous material or product may be characterized by pores with an average size of no more than about 10 mm, 9 mm, 8 mm, 7 mm, 6 mm, 5 mm, 4 mm, 3 mm, 2 mm, 1 mm, 750 μm, 500 μm, 250 μm, 100 μm, 10 μm, 1 μm, 100 nm, 10 nm, or less than 10 nm.

In some cases, manufactured textiles such as fabrics may be characterized by a particular thread count. A thread count may be defined as the number of horizontal and vertical threads per square inch of the textile material. A textile may have a thread count of about 50, 100, 150, 200, 250, 300, 350, 400, 450, 500, 550, 600, 650, 700, 750, 800, 850, 900, 950, 1000, or more than about 1000. A textile may have a thread count of at least about 50, 100, 150, 200, 250, 300, 350, 400, 450, 500, 550, 600, 650, 700, 750, 800, 850, 900, 950, 1000, or more than about 1000. A textile may have a thread count of no more than about 1000, 950, 900, 850, 800, 750, 700, 650, 600, 550, 500, 450, 400, 350, 300, 250, 200, 150, 100, 50 or less than about 50.

A material may have a characteristic surface topology, morphology, or roughness. The topology may be regular, patterned, irregular, or amorphous. A surface roughness of a material may be quantified as the average deviation in surface height along a measured line or over a measured area, as determined by a method such as profilometry. A material may be considered smooth if its surface roughness is below a threshold value, such as the limit of human visible detection (e.g., less than 10 μm). A material may be considered rough if its surface roughness exceeds a threshold value, such as the limit of human visible detection. A material may have a surface roughness of at least about 1 nm, 10 nm, 100 nm, 1 μm, 10 μm, 100 μm, 250 μm, 500 μm, 1 mm, 2 mm, 3 mm, 4 mm, 5 mm, 6 mm, 7 mm, 8 mm, 9 mm, 10 mm, or more than about 10 mm. A material may have a surface roughness of less than about 10 mm, 9 mm, 8 mm, 7 mm, 6 mm, 5 mm, 4 mm, 3 mm, 2 mm, 1 mm, 750 μm, 500 μm, 250 μm, 100 μm, 10 μm, 1 μm, 100 nm, 10 nm, 1 nm, or less than about 1 nm.

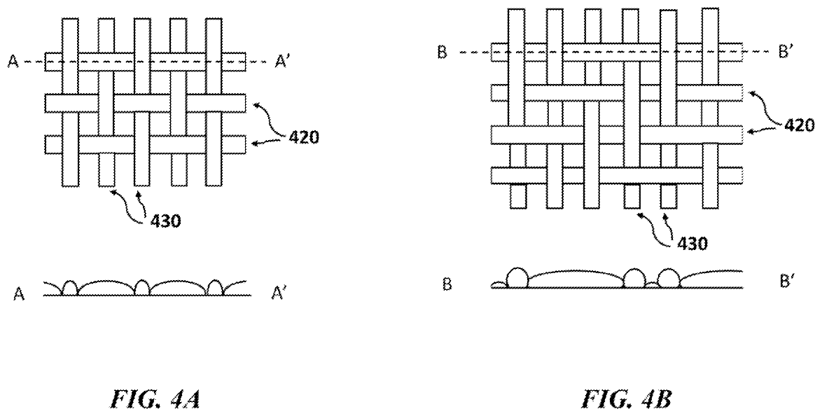

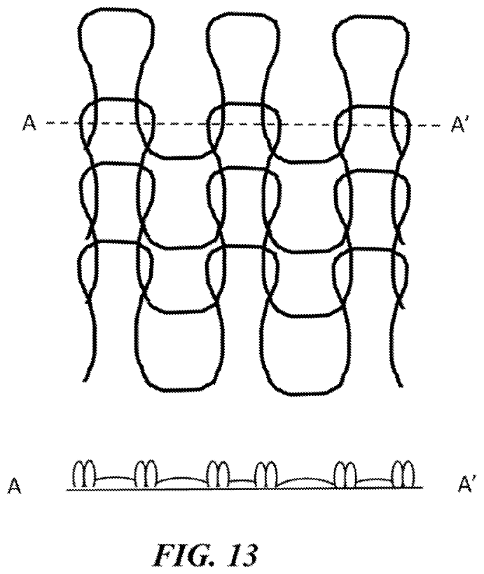

A material may have a patterned surface morphology. The patterning or morphology of the material may be an inherent characteristic or may arise due to a method of manufacturing. FIGS. 4A-B and FIG. 13 present examples of surface patterning caused by the manufacturing method of a fabric material. FIG. 4A shows a fabric material with a plain weave of yarn threads. The weft threads 420 are woven alternatively over or under the warp threads 430 to produce a uniform weaving pattern. At the bottom of FIG. 4A, a cross-section along trace A-A′ shows the surface topology caused by the stitching pattern in closer detail. FIG. 4B shows a fabric material with a twill weave of yarn threads. The weft threads 420 are woven over two warp threads 430, then woven under two warp threads 430 in a repeating pattern. At the bottom of FIG. 4B, a cross-section along trace B-B′ shows the surface topology caused by the stitching pattern in a closer detail. Based upon the variation in the manufacturing methods of the material depicted in FIGS. 4A and 4B, the surface topology can be seen to differ. Similarly, FIG. 13 depicts a knitted fabric with a plain knitting pattern. At the bottom of FIG. 13 is a cross-section along axis A-A′ showing the surface topology caused by the stitching pattern.

Materials or products may be opaque, transparent, reflective, non-reflective, or translucent. The transparency or opacity of a material or product may vary depending upon the wavelength of light impinging upon the surface of the material or product. In some cases, a material may have a characteristic transparency or opacity. The transparency or opacity may be uniform throughout the material or may vary in a regular or irregular manner. Transparency or transmittance may be defined as the total amount of light that passes through a material. A material monitored by an optical detection system may have a characteristic average transmittance of about 99.9%, 99%, 95%, 90%, 85%, 80%, 75%, 70%, 65%, 60%, 55%, 50%, 45%, 40%, 35%, 30%, 25%, 20%, 15%, 10%, 5% or less than about 5%. A material monitored by an optical detection system may have a characteristic average transmittance of at least about 99.9%, 99%, 95%, 90%, 85%, 80%, 75%, 70%, 65%, 60%, 55%, 50%, 45%, 40%, 35%, 30%, 25%, 20%, 15%, 10%, 5% or less than about 5%. A material monitored by an optical detection system may have a characteristic average transmittance of at least about 5%, 99%, 10%, 15%, 20%, 25%, 30%, 35%, 40%, 45%, 50%, 55%, 60%, 65%, 70%, 75%, 80%, 85%, 90%, 95%, 99% or more than 99.9%.

Materials or products produced from a manufacturing process may contain defects or may be substandard materials or products. Defects or substandard materials or products may arise during a subsequent process that occurs after the initial manufacturing of the material or product. Defects or substandard materials or products may arise from the raw materials used to create the material or product. For example, flaws in yarn used in a textile manufacturing process may create defects in a produced fabric where the yarn flaws are incorporated. Defects or substandard materials or products may arise from the equipment used to manufacture the material or product. For example, a broken or damaged needle in a knitting machine may regularly or irregularly incorporate defects into a fabric. Defects or substandard materials or products may arise from the process used to manufacture the material or product. For example, an unexpected shift in processing conditions (e.g., an ambient humidity level) may alter or otherwise affect the finished product from a manufacturing process. Defects or substandard materials or products may arise inherently during the production of materials or products, or may occur due to unplanned circumstances such as malfunctioning manufacturing machinery or compromised raw materials for production. Defects or substandard materials or products may arise from a human error, including improper construction of manufacturing devices, improper setup and installation of manufacturing devices, improper initialization of manufacturing devices, improper operation of manufacturing devices, and/or improper programming of software or other control systems. Human errors may further include failure to detect defects or substandard materials or products due to inexperience, fatigue, oversight, or other issues relating to manual visual or physical inspection.

Defects may be deemed to be minor or major defects. A minor defect may comprise a defect that does not render a material or product unusable or unsellable. A major defect may comprise a defect that renders a material or product unusable, unsellable, or otherwise compromises the properties of the product. In some cases, a plurality of minor defects may comprise a major defect if the additive effect of the plurality of minor defects renders the material or product unusable, unsellable, or otherwise compromises the properties of the product. Substandard materials or products may be downgraded to a lower grade of material or product. In some cases, a substandard material or product may be unusable, unsellable, or otherwise compromised. An optical detection system may be capable of identifying major defects, minor defects, or substandard materials or products.

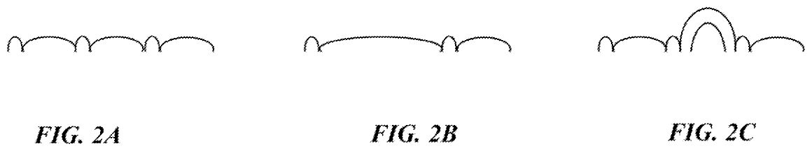

Defects may alter the surface topology or morphology of a material. The nature or type of a defect may be determined by an observation of the topology or morphology of the surface of a material. Defects may have a characteristic morphology or topology that distinguishes the defects from a non-defective material or from other defect types. FIGS. 2A-2C compare surface topologies for cross-sections of a fabric material. FIG. 2A shows a normal surface topology for a fabric material with a plain weave. FIG. 2B shows a surface topology containing a missed stitch for the same fabric material as that depicted in FIG. 2A. FIG. 2C shows a surface topology containing a loose yarn thread for the same fabric material as that depicted in FIG. 2A. The distinct differences in surface morphology make distinguishing defect presence and defect type possible in comparison to the normal manufactured fabric.

Defects in a material or product may occur at a characterizable rate. In some cases, defects in a material or product may occur randomly. In other cases, defects in a material or product may occur regularly. The rate of occurrence for defects may differ based upon the stage or step in manufacture of a material or product. Defects may be known to occur at differing rates during transient phases of a manufacturing process such as start-up, stopping, or changing of process feeds.

The rate of occurrence of defects or substandard materials or products may be correlated to a material or product processing parameter. For example, defects or substandard materials or products may occur at a known rate per time, at a known rate per area of material produced, at a known rate per volume of material produced, at a known rate per length of material produced, or at a known rate per weight of material produced. Minor defects and major defects may occur at differing rates. In some cases, a threshold rate of defect occurrence may occur at or beyond which a material or product is considered unusable, unsellable or otherwise compromised.

Optical detection systems with illumination modules may be utilized to identify defects or substandard quality in materials or products. Optical detection systems with illumination modules may be utilized to determine the defect rate or quality level of materials or products during a manufacturing process. An optical detection system with an illumination module may be capable of identifying a plurality of types of defects or quality levels. An optical detection system with an illumination module may be capable of identifying minor defects and major defects or substandard materials or products in a produced material or product. An optical detection system with an illumination module may be capable of quantifying a rate of occurrence for minor and/or major defects or substandard materials or products during the production or processing of a material or product.

Defects in manufactured materials or products may include any damage or irregularity in the form or structure of the material or product. Defects may occur at any length scale from microscale to macroscale. A defect may be characterized by a characteristic size such as a defect length, defect width, defect depth, defect thickness, defect diameter, defect area, or defect volume. Defects in materials may include holes, cracks, fractures, pits, pores, depressions, tears, burns, stains, bends, breaks, domains of thinning, domains of thickening, stretches, compressions, bulges, deformations, discontinuities, missing substituents, blockages, occlusions, or unwanted inclusions.

A defect may have a characteristic dimension associated with it. An optical detection system may be capable of identifying a defect at a given length scale. A defect may have an average dimension (e.g., length, width, depth, thickness, diameter) of about 100 nanometers (nm), 500 nm, 1 micrometer (μm), 5 μm, 10 μm, 25 μm, 50 μm, 100 μm, 200 μm, 250 μm, 500 μm, 750 μm, 1 mm, 2 mm, 3 mm, 4 mm, 5 mm, 6 mm, 7 mm, 8 mm, 9 mm, 1 cm, 2 cm, 3 cm, 4 cm, 5 cm, 6 cm, 7 cm, 8 cm, 9 cm, 10 cm, or more than 10 cm. A defect may have an average dimension (e.g., length, width, depth, thickness, diameter) of at least about 100 nanometers (nm), 500 nm, 1 micrometer (μm), 5 μm, 10 μm, 25 μm, 50 μm, 100 μm, 200 μm, 250 μm, 500 μm, 750 μm, 1 mm, 2 mm, 3 mm, 4 mm, 5 mm, 6 mm, 7 mm, 8 mm, 9 mm, 1 cm, 2 cm, 3 cm, 4 cm, 5 cm, 6 cm, 7 cm, 8 cm, 9 cm, 10 cm, or more than 10 cm. A defect may have an average dimension (e.g., length, width, depth, thickness, diameter) of no more than about 10 cm, 9 cm, 8 cm, 7 cm, 6 cm, 5 cm, 4 cm, 3 cm, 2 cm, 1 cm, 9 mm, 8 mm, 7 mm, 6 mm, 5 mm, 4 mm, 3 mm, 2 mm, 1 mm, 750 μm, 500 μm, 250 μm, 200 μm, 100 μm, 50 μm, 25 μm, 10 μm, 5 μm, 1 μm, 500 nm, 100 nm, or less than 100 nm. A defect may have a characteristic average area of at least about 0.01 μm², 0.1 μm², 1 μm², 10 μm², 100 μm², 1000 μm², 10000 μm², 100000 μm², 1 mm², 10 mm², 1 cm², 10 cm², 100 cm², or more than about 100 cm². A defect may have a characteristic average area of no more than about 100 cm², 10 cm², 1 cm², 10 mm², 1 mm², 100000 μm², 10000 μm², 1000 μm², 100 μm², 10 μm², 1 μm², 0.1 μm², 0.01 μm², or less than about 0.01 μm².

Defects may occur in a material or product at regular or irregular intervals. Defects may occur with a particular density. For example, a material or product may have a rate of defects per unit length (μm, mm, cm, m, etc.), per unit area (μm², mm², cm², m², etc.), per unit volume (μm³, mm³, cm³, m³, etc.), or per unit weight (kg, lb, ton, metric ton, etc.). In some materials or products, defects may be expected to occur at or below a particular number density. In some manufacturing processes, a material or product may be discarded if the defect rate exceeds a threshold number density. A material or product may have a defect rate with a number density (e.g., defects per unit length, defects per unit area, defects per unit volume, or defects per unit weight) of about 1, 2, 3, 4, 5, 6, 7, 8, 9, 10, 15, 20, 25, 30, 35, 40, 45, 50, 55, 60, 65, 70, 75, 80, 85, 90, 95, 100, 110, 120, 130, 140, 150, 160, 170, 180, 190, 200, 300, 400, 500, 600, 700, 800, 900, 1000 or more than 1000. A material or product may have a defect rate with a number density of at least about 1, 2, 3, 4, 5, 6, 7, 8, 9, 10, 15, 20, 25, 30, 35, 40, 45, 50, 55, 60, 65, 70, 75, 80, 85, 90, 95, 100, 110, 120, 130, 140, 150, 160, 170, 180, 190, 200, 300, 400, 500, 600, 700, 800, 900, 1000 or more than about 1000. A material or product may have a defect rate with a number density of no more than about 1000, 900, 800, 700, 600, 500, 400, 300, 200, 190, 180, 170, 160, 150, 140, 130, 120, 110, 100, 95, 90, 85, 80, 75, 70, 65, 60, 55, 50, 45, 40, 35, 30, 25, 20, 15, 10, 9, 8, 7, 6, 5, 4, 3, 2, 1 or less than about 1. An optical detection system utilizing an illumination module may quantify the number density of defects in a manufactured material or product. An optical detection system utilizing an illumination module may quantify the number density of defects in a manufactured material or product as the material passes through an illumination area created by the illumination module.

In some cases, an optical detection system with an illumination module may be utilized to detect defects or substandard materials or products during textile or fabric production or processing. Detected textile or fabric defects may include: broken yarn, laddering, holes, floats, knots, needle defects (complete, needle does not pull the yarn), contamination defects by oils, solvents, etc. (oil spots caused by common oil leaks), needle defects (incomplete, needle incorrectly pulls the yarn), needle and sinker defects (uniformity caused by incorrect combination between sinker and needle, leading to non-uniformities), continuous elastane defect (commonly called Lycra defect, or spandex defect—which is barely detectable by humans during production, only after several phases of knitting), dashed elastane defects (same structure flaw as continuous elastane defect, but dashed, more rare and less visible—also barely detectable by humans during production, only after several phases of knitting), contamination by other fibers (when fibers from other sources imprudently get in production, causing spots with different material), contamination by other colors (when fibers from other sources imprudently get in the production causing spots with different colors), unwanted hairiness, yarn non-uniform width and other yarn irregularities, non-uniform distance between wales (columns) or courses (rows), and non-uniformities on the production fabrics.

### Material Characterization Using Light

Illumination modules may be utilized to direct light to a surface of a material during or after a manufacturing process or a post-manufacturing process. Interactions of the directed light, such as reflection, refraction, absorbance, transmittance, and scattering, may be measured to determine a material characteristic of the manufactured material. Material characteristics of a manufactured material may include index of refraction, reflectance, absorptivity, color, opacity, luminescence, diffraction, birefringence, luster, and roughness. A material characteristic may be a direct or indirect measure of material quality. For example, a material may pass a quality assurance protocol by a direct characteristic if its roughness is less than a threshold value. Alternatively, a material may pass a quality assurance protocol by an indirect characteristic, for example opacity may be used as an indirect measure of thread count in a fabric material.

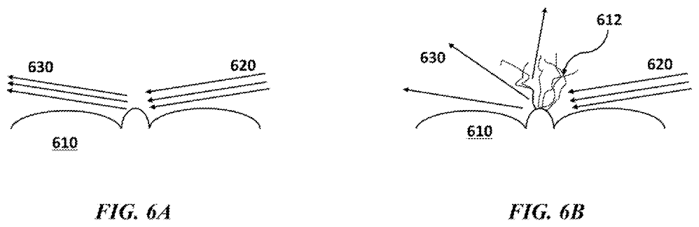

Illumination modules may be utilized to detect defects in a material during or after a manufacturing process. Illumination modules may direct light toward a region through which a manufactured material passes during a manufacturing process or subsequent processing step. Interactions of the directed light, such as reflection, refraction, absorbance, transmittance, and scattering, may be measured to determine the presence or absence of a defect in a manufactured material. In some cases, a defect or series of defects may be determined by a variance, change, or deviation in a measured material property in a localized, variable, irregular, random, repeating, or patterned interval. For example, localized fraying of yarn in a woven fabric material may be detected based upon an attenuation of reflected light. FIGS. 6A-B show a schematic view of light interacting with a textured material surface with varying surface conditions. In FIG. 6A, a light beam 620 is directed at a low angle toward a surface feature on a fabric surface 610. The light beam 620 is fully reflected by the fabric surface 610, creating outgoing light beam 630. In FIG. 6B, a fraying defect on a thread of yarns creates stray fibers 612 on the fabric surface 610. The directed light beam 620 is scattered by the stray fibers 612, causing outgoing light beam 630 to be attenuated relative to the incoming light beam 620.

An illumination module may be utilized for material inspection, quality assurance or defect detection in a material manufacturing process using light that has been applied in an optimized fashion. An illumination module may direct, scale, organize, or time the application of light to a surface of a material. Light direction may refer to orientation of the light beam emitted by the illumination module toward a surface of a material. Light scaling may refer to quantitative properties of the emitted light beam, such as power and power density. Light organization may refer to the ordering of light as it is emitted from the illumination module. Light timing may refer to pattern of light emission from the module as a function of time.

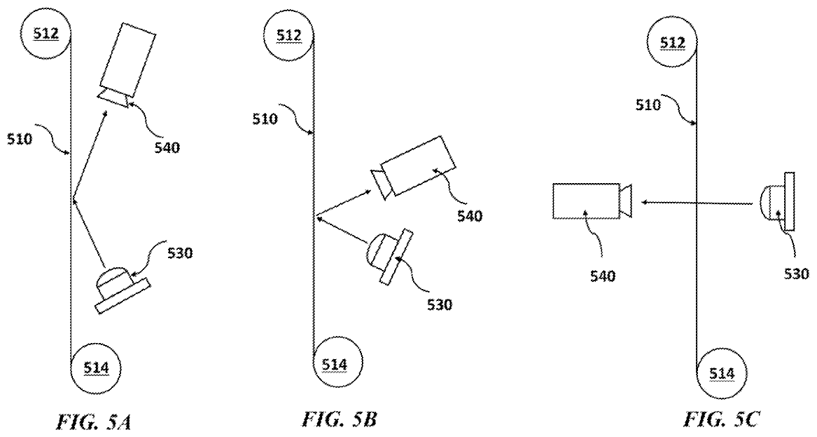

An illumination module may direct light on to the surface of a material for the purposes of material inspection, quality assurance or defect detection. Illumination modules may generate light in an illumination area or target region through which a manufactured material passes, translates, or otherwise moves. An illumination module may be positioned to apply the incident light beam to a material surface at a preferred or optimal angle. FIGS. 5A-5C show various configurations of an illumination module 530 relative and a light sensor 540 relative to the surface of a material 510 being produced from a top roll 512 to a bottom roll 514 in a roll-to-roll manufacturing process. In FIG. 5A, the illumination module 530 and light sensor 540 are oriented at a relatively shallow angle to the surface of the material 510. In FIG. 5B, the illumination module 530 and light sensor 540 are oriented at a high angle relative to the surface of the material 510. In FIGS. 5A and 5B, the light sensor 540 is configured to detect a reflection of light off the surface of the material 510 In FIG. 5C, the illumination module 530 is oriented orthogonally to the surface of the material 510, and is directed to a co-axial light sensor 540. The configuration of FIG. 5C depicts a form of material characterization based upon transmittance or absorbance of light. Light direction may also include processes such as reflecting, refracting, and/or turning a light beam after it has been emitted from an illumination module. An illumination module may be used to illuminate the surface of a static or moving material where the material is flat or substantially flat. An illumination module may be used to illuminate the surface of a static or moving material where the material is not flat. FIGS. 5A-5C show a configuration of a material produced in a roll-to-roll fashion where the material 510 is fed from roll 512 to roll 514 while being monitored by a sensor 540 and an illumination module 530 that illuminates a target region near the center of the flat material sheet 510. In some alternative cases, a material may be fed from a first roll to a second roll by passing over a third roll, creating a curved surface of material sheet. The sensor may be configured to detect light from an illumination module impinging upon the curved surface of the material sheet.

An illumination module may scale light that is emitted for the purposes of quality assurance or defect detection of a material. The illumination module may emit a light beam with a particular power, power density, wavelength, spectrum of wavelengths, length, or width.

An illumination module may have a total power consumption or output of at least about 1 Watt (W), 10 W, 20 W, 30 W, 40 W, 50 W, 60 W, 70 W, 80 W, 90 W, 100 W, 150 W, 200 W, 300 W, 400 W, 500 W, 750 W, 1 kiloWatt (kW), 10 kW, or more than 10 kW. An illumination module may have a total power consumption or output of at most about 10 kW, 1 kW, 750 W, 500 W, 400 W, 300 W, 250 W, 200 W, 150 W, 100 W, 90 W, 80 W, 70 W, 60 W, 50 W, 40 W, 30 W, 20 W, 10 W, 1 W, or less than about 1 W.

An illumination module may have a characteristic power density of emitted light. The power density of light emitted from an illumination module may be measured at some distance relative to the light-emitting regions of the illumination module (e.g., at the module surface, at a material surface, at a distance between a module and a material). The power density of light emitted from an illumination module may be constant at any distance from the illumination module (e.g., for a collimated beam). The power density of light emitted from an illumination module may increase with distance from the illumination module (e.g., a focused beam). The power density of light emitted from an illumination module may decrease with distance from the illumination module (e.g., a defocused, scattered, or filtered beam). An illumination module may have a light power density at a certain distance from the module of at least about 0.001 Watt per square centimeter (W/cm²), 0.01 W/cm², 0.1 W/cm², 1 W/cm², 10 W/cm², 100 W/cm², 1000 W/cm², 10000 W/cm², or more than about 10000 W/cm². An illumination module may have a light power density at a certain distance from the module of no more than about 10000 W/cm², 1000 W/cm², 100 W/cm², 10 W/cm², 1 W/cm², 0.1 W/cm², 0.01 W/cm², 0.001 W/cm², or less than about 0.001 W/cm². The light power density may be measured at a distance from the illumination module of about 0 mm, 1 mm, 5 mm, 1 cm, 5 cm, 10 cm, 50 cm, 100 cm, 500 cm, 1 m, or more than 1 m. The light power density may be measured at a distance from the illumination module of at least about 0 mm, 1 mm, 5 mm, 1 cm, 5 cm, 10 cm, 50 cm, 100 cm, 500 cm, 1 m, or more than 1 m. The light power density may be measured at a distance from the illumination module of no more than about 10 m, 500 cm, 100 cm, 50 cm, 10 cm, 5 cm, 1 cm, 5 mm, 1 mm or less than 1 mm.

An illumination module may comprise a single light, a group of lights, or a series of lights. A light source or illumination unit in an imaging unit may comprise a substantially monochromatic light source or a light source with a characteristic frequency or wavelength range. Exemplary light sources or illumination units may include x-ray sources, ultraviolet (UV) sources, infrared sources, LEDs, fluorescent lights, and lasers. A light source or illumination unit may emit light within a defined region of the electromagnetic spectrum, such as x-ray, UV, UV-visible, visible, near-infrared, far-infrared, or microwave. A light source or illumination unit may have a characteristic wavelength of about 0.1 nm, 1 nm, 10 nm, 100 nm, 200 nm, 300 nm, 400 nm, 500 nm, 600 nm, 700 nm, 800 nm, 900 nm, 1 μm, 10 μm, 100 μm, 1 mm, or more than about 1 mm. A light source or illumination unit may have a characteristic wavelength of at least about 0.1 nm, 1 nm, 10 nm, 100 nm, 200 nm, 300 nm, 400 nm, 500 nm, 600 nm, 700 nm, 800 nm, 900 nm, 1 μm, 1.2 μm, 5 μm, 10 μm, 100 μm, 1 mm, or more than 1 mm. A light source or illumination unit may have a characteristic wavelength of no more than about 1 mm, 100 μm, 10 μm, 5 μm, 1.2 μm, 1 μm, 900 nm, 800 nm, 700 nm, 600 nm, 500 nm, 400 nm, 300 nm, 200 nm, 100 nm, 10 nm, 1 nm, 0.1 nm, or less than about 0.1 nm. A light source or illumination unit may emit light having a range of wavelengths, for example in a range from about 1 nm to about 10 nm, about 1 nm to about 100 nm, about 10 nm to about 100 nm, about 10 nm to about 400 nm, about 10 nm to about 500 nm, about 10 nm to about 1000 nm, about 10 nm to about 1200 nm, about 100 nm to about 500 nm, about 100 nm to about 700 nm, about 200 nm to about 500 nm, about 400 nm to about 700 nm, about 700 nm to about 1 μm, about 700 nm to about 10 μm, about 1 μm to about 100 μm, or about 1 μm to about 1 mm.

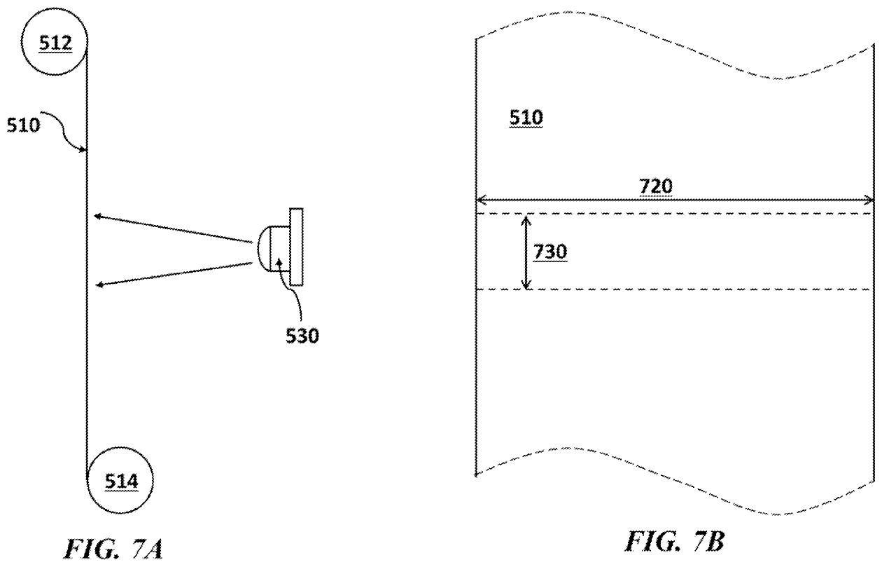

An illumination module may produce a light beam with a chosen length or width. Light beams with unidirectional light direction (e.g., collimated beams) may have a fixed length or width when projected onto the surface of a material. Light beams with a multi-directional light direction (e.g., non-collimated beams, focused beams) may have a length or width when projected onto the surface of a material that may be varied by altering the distance or direction of the illumination module relative to the material surface. FIGS. 7A and 7B depict the projection area of a light beam from an illumination module onto a material surface. FIG. 7A depicts a side view of a material sheet 510 transferring from a top roll 512 to a bottom roll 514 during a manufacturing process. The material sheet 510 is illuminated by a non-collimated beam from an illumination module 530. FIG. 7B shows a front-side view of the surface of the material sheet 510 with a projection of the illuminated area of the sheet bounded by dashed lines. The illuminated area on the sheet has a measurable length 720 corresponding to the entire width of the material sheet 510, and a measurable width 730. Moving the illumination module closer to the material surface can decrease the width 730 while increasing the power density of light on the material surface, but may not affect the length 720 of the illuminated area. In some cases, illumination modules may create light beams that project onto a material surface in non-rectangular shapes, such as circles or ovals. Characteristic lengths and or widths for non-rectangular objects may refer to measurable dimensions such as diameters or radii.

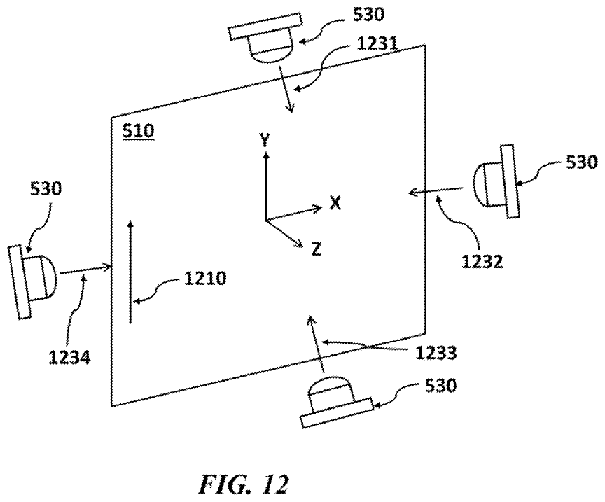

The orientation of a light beam directed toward a target material from a manufacturing process or subsequent processing process may be defined relative to an axis representing the position of the material. When a manufactured material is moving, the axis or orientation may be defined relative to the material surface at a fixed instant of time. In some cases, the orientation of the light beam may be determined relative to an axis that is in the plane of a material sheet with the axis aligned parallel to the direction of travel for the material sheet. In other cases, the axis may be aligned at a differing angle, such as orthogonal to the direction of travel for the material sheet. In some cases, the orientation of a light beam may be defined by an axis that is parallel to the direction of emitted light or the average direction of emitted light. In some cases, the direction of the axis of emitted light may be transverse or orthogonal to the axis of alignment for the material sheet onto which the light beam is projected. The axis of orientation for an emitted light beam may be characterized by an angle relative to the axis of orientation for the material sheet. FIG. 12 depicts varying positions for an illumination module 530 relative to a material sheet 510. The material sheet being produced or processed travels in a direction parallel to arrow 1210. Within the plane of the face of the material sheet 510, various axes of orientation for the material sheet 510 may be defined, such as depicted axis X (coplanar with the sheet, orthogonal to the direction of travel 1210), axis Y (coplanar with the sheet, parallel to the direction of travel 1210), or axis Z (orthogonal to axes X and Y). Illumination modules 530 are depicted in four differing configurations relative to the material sheet 510. Each of the four differing configurations has an associated axis of orientation for the light beam (1231, 1232, 1233, and 1234, respectively). An angle may be defined between the axis of orientation for a material sheet 510 and the axis of orientation for the light beam.

The axis of orientation for the emitted light beam may be about 1 degree (°), 2°, 3°, 4°, 5°, 6°, 7°, 8°, 9°, 10°, 15°, 20°, 25°, 30°, 35°, 40°, 45°, 50°, 55°, 60°, 65°, 70°, 75°, 80°, 81°, 82°, 83°, 84°, 85°, 86°, 87°, 88°, 89°, 90°, 91°, 92°, 93°, 94°, 95°, 96°, 97°, 98°, 99°, 100°, 105°, 120°, 135°, 150°, 165°, 170°, 171°, 172°, 173°, 174°, 175°, 176°, 177°, 178°, 179°, 180°, 181°, 182°, 183°, 184°, 185°, 186°, 187°, 188°, 189°, 190°, 195°, 210°, 225°, 240°, 255°, 270°, 285°, 300°, 315°, 330°, 345°, 350°, 351°, 352°, 353°, 354°, 355°, 356°, 357°, 358°, 359°, or about 360° relative to an axis of orientation of a material. The axis of orientation for the emitted light beam may be at least about 1 degree (°), 2°, 3°, 4°, 5°, 6°, 7°, 8°, 9°, 10°, 15°, 20°, 25°, 30°, 35°, 40°, 45°, 50°, 55°, 60°, 65°, 70°, 75°, 80°, 81°, 82°, 83°, 84°, 85°, 86°, 87°, 88°, 89°, 90°, 91°, 92°, 93°, 94°, 95°, 96°, 97°, 98°, 99°, 100°, 105°, 120°, 135°, 150°, 165°, 170°, 171°, 172°, 173°, 174°, 175°, 176°, 177°, 178°, 179°, 180°, 181°, 182°, 183°, 184°, 185°, 186°, 187°, 188°, 189°, 190°, 195°, 210°, 225°, 240°, 255°, 270°, 285°, 300°, 315°, 330°, 345°, 350°, 351°, 352°, 353°, 354°, 355°, 356°, 357°, 358°, 359°, or more than 359° relative to an axis of orientation of a material. The axis of orientation for the emitted light beam may be no more than about 360 degree)(°, 359°, 358°, 357°, 356°, 355°, 354°, 353°, 352°, 351°, 350°, 345°, 330°, 315°, 300°, 285°, 270°, 255°, 240°, 225°, 210°, 195°, 190°, 189°, 188°, 187°, 186°, 185°, 184°, 183°, 182°, 181°, 180°, 179°, 178°, 177°, 176°, 175°, 174°, 173°, 172°, 171°, 170°, 165°, 150°, 135°, 120°, 105°, 100°, 99°, 98°, 97°, 96°, 95°, 94°, 93°, 92°, 91°, 90°, 89°, 88°, 87°, 86°, 85°, 84°, 83°, 82°, 81°, 80°, 75°, 70°, 65°, 60°, 55°, 50°, 45°, 40°, 35°, 30°, 25°, 20°, 15°, 10°, 9°, 8°, 7°, 6°, 5°, 4°, 3°, 2°, 1°, or less than about 1° relative to the axis of orientation of a material.

An illumination module may produce a light beam with a length or width of at least about 1 mm, 5 mm, 1 cm, 5 cm, 10 cm, 15 cm, 20 cm, 25 cm, 30 cm, 40 cm, 50 cm, 100 cm, 200 cm, 250 cm, 500 cm, 1 m, or more than 1 m. An illumination module may produce a light beam with a length or width of no more than about 1 m, 500 cm, 250 cm, 200 cm, 100 cm, 50 cm, 40 cm, 30 cm, 25 cm, 20 cm, 15 cm, 10 cm, 5 cm, 1 cm, 5 mm, 1 mm, or less than 1 mm.

An illumination module may organize the light that is emitted for the purposes of quality assurance or defect detection of a material. Light organization may include processes such as collimation, de-collimation, focusing, de-focusing, polarizing, de-polarizing, scattering, and filtering. An illumination module may contain one or more optical elements for organizing light. Light organizing elements may include direction-altering elements and intensity-altering elements. Exemplary direction-altering elements may include collimating lenses, focusing lenses, focusing mirrors, defocusing lenses, defocusing mirrors, planar mirrors, parabolic mirrors, polygon rotating mirrors, and polarizing lenses. Exemplary intensity-altering elements may include filtering lenses, beam splitters, dichroic mirrors, irises, apertures, semi-transparent materials, attenuators, patterned attenuators, and openings. An opening, aperture, or iris may be fixed or adjustable. A light beam may emerge from an opening, aperture, or iris at an angle from 1 degree to 80 degrees. In some embodiments, a light beam may emerge from an opening, aperture, or iris at an angle of no more than about 45 degrees. An opening, iris, or aperture may be symmetrical (e.g., emitting light at the same outgoing angle on all sides) or non-symmetrical (e.g., emitting light at a skewed or slanted angle). An illumination module may contain one or more lenses for purposes such as collimation, focusing, polarization, and filtering. An optical element of an illumination module may be chosen for light of a certain wavelength or light within a particular spectrum of wavelengths. For example, a collimating lens may collimate visible light while permitting UV or IR light to pass through without collimation. An optical element may comprise any suitable material, including transparent or translucent plastics, transparent or translucent glasses, reflective metals, and reflective coatings.

An organized light beam may have the characteristic organization of the optical elements through which it has passed. For example, a collimating or polarizing component will not perfectly collimate or polarize the light beam, but rather will collimate or polarize the light beam to the efficiency of the optical element. For the purposes of this disclosure, an organized light beam refers to a light beam that has passed through an organizing optical element (e.g., a collimated light beam is a light beam that has passed through a collimating lens). A beam of light may be considered quasi-organized (e.g., quasi-collimated, quasi-polarized, quasi-filtered, quasi-defocused, etc.) if the beam of light has desired beam characteristic (e.g., collimation, polarization, filtering, defocusing, etc.) for at least about 80%, 85%, 90%, 95%, 96%, 97%, 98%, 99%, 99.5%, 99.9%, or more than about 99.9% of the light output of the beam. For example, a quasi-collimated beam may have at least about 80% of its light oriented parallel to an axis of collimation. An additional example may be a quasi-filtered light beam that has at least about 80% of its light fall within a characteristic output spectrum of the filtering element.

A light beam may emit light that is emitted at some angle relative to the primary directional axis of the light beam. For example, light passing through an opening or aperture may have a primary directional axis that is orthogonal to the surface of the opening or aperture. A light beam may contain light that has an angle of about 1 degree)(°, 2°, 3°, 4°, 5°, 6°, 7°, 8°, 9°, 10°, 15°, 20°, 25°, 30°, 35°, 40°, 45°, 50°, 55°, 60°, 65°, 70°, 75°, 80°, or more than about 80° relative to the primary directional axis of the light beam. A light beam may contain light that has an angle of at least about 1 degree)(°, 2°, 3°, 4°, 5°, 6°, 7°, 8°, 9°, 10°, 15°, 20°, 25°, 30°, 35°, 40°, 45°, 50°, 55°, 60°, 65°, 70°, 75°, 80°, or more than about 80° relative to the primary directional axis of the light beam. A light beam may contain light that has an angle of no more than about 80°, 75°, 70°, 65°, 60°, 55°, 50°, 45°, 40°, 35°, 30°, 25°, 20°, 15°, 10°, 9°, 8°, 7°, 6°, 5°, 4°, 3°, 2°, 1°, or less than about 1° relative to the primary directional axis of the light beam.

An illumination module may time the emission and direction of a light beam that is emitted for the purposes of quality assurance or defect detection of a material. An illumination module may continuously emit a light. An illumination module may emit light in a temporally-patterned fashion, such as strobing or blinking. An illumination module may emit light in an irregular or random temporal fashion. An illumination module may contain an array of light sources that emit light in a patterned fashion. An array of light sources may emit lights simultaneously or may be patterned to alternate output in a regular or irregular pattern. An illumination module may contain an array of light sources that emit at differing wavelengths. An illumination module may emit different wavelengths or spectrums of wavelengths with uniform or differing temporal patterns. For example, an illumination module may contain a visible light source that strobes with a 10 second period and an infrared light source that strobes with a 1 second period.

An illumination module may produce a uniform intensity of light on a material surface. An illumination module may produce a uniform intensity of light on a material surface within a defined target region. An illumination module may produce a non-uniform or patterned illumination within a target region on a material surface (e.g., a sinusoidal pattern with alternation between higher intensity light and lower intensity light along a linear trace). An illumination system may comprise more than one illumination module. An illumination module may comprise multiple illumination modules with the same or differing light output characteristics (e.g., light intensity, wavelength, frequency, focal distance, etc.). Two or more illumination modules may be configured to project light onto the same or overlapping target regions on a material surface. Two or more illumination modules may be configured to illuminate the same target region at differing angles of illumination. Two or more illumination modules may be configured to illuminate differing target regions of a material surface.

An illumination module may be spaced at a particular distance from another illumination module. An illumination module may be spaced at least about 1 cm, 5 cm, 10 cm, 20 cm, 50 cm, 1 m, 2 m or more than 2 m from a second illumination module. An illumination module may be spaced no more than about 2 m, 1 m, 50 cm, 20 cm, 10 cm, 5 cm, 1 cm, or less than 1 cm from a second illumination module.

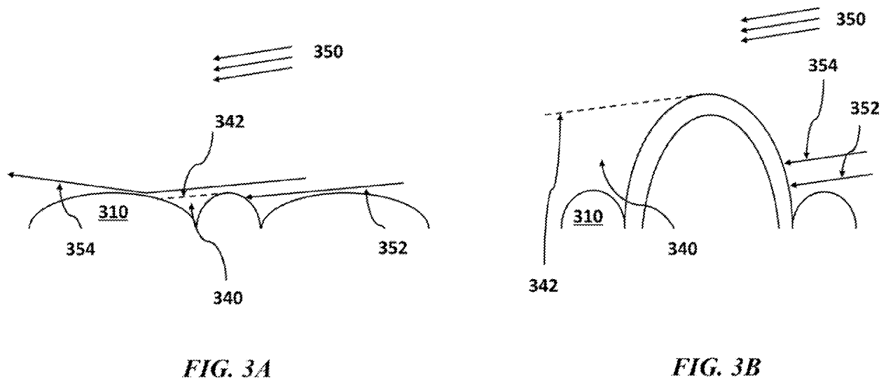

An illumination module that is incident upon a material may produce patterns or outputs of light when the module directs a light beam onto a surface of a material. The pattern or output may comprise a pattern or output of reflected, refracted, scattered, or transmitted light. In some cases, reflection, scattering, or absorbance of light incident upon a surface of a material may produce shadowing of one or more portions of the surface. A material may have a characteristic shadowing pattern when light is directed at the surface at a particular angle. The pattern or output of light from the surface of a material may be utilized for quality assurance or defect detection of the material. FIGS. 3A and 3B depict an exemplary use of shadow patterning to detect a defect in a fabric material. FIG. 3A shows an incident light beam 350 with a shallow approach angle from an illumination module. An incoming light ray 352 contacts a regular surface feature of the fabric material 310. The incoming light ray 352 is reflected off the surface of the material 310, producing an outgoing light ray 354. Due to shadowing created by the surface feature, light cannot directly reach the region bounded by trace 342, producing a shadowed region 340. FIG. 3B shows the effect of a shallow incident light beam 350 when encountering a loose thread in the fabric material 310. The incoming light ray 352 is more likely to be blocked by the much larger surface feature created by the loose thread, reflecting one or more reflected outgoing light rays 354. The larger surface feature creates a larger shadowed region 340 over portion of the material surface within the bounds of trace 342. A sensor may be utilized to detect patterns or outputs of shadowing or other light interactions with a material. Patterns or outputs of light interactions with a material may be used for quality assurance or defect detection by comparing to known or observed patterns or outputs of light interactions with the material. In some cases, the interaction of light with a defect or surface feature may produce a light pattern (e.g. a shadow or bright region) that is larger than the size of the defect. In some cases, the interaction of light with a defect or surface feature may produce a detectable light pattern from a defect that is too small to be perceived by the human eye. In some cases, the interaction of light with a defect or surface feature may produce a detectable pattern that may be detected by an imaging system such as a camera sensor.

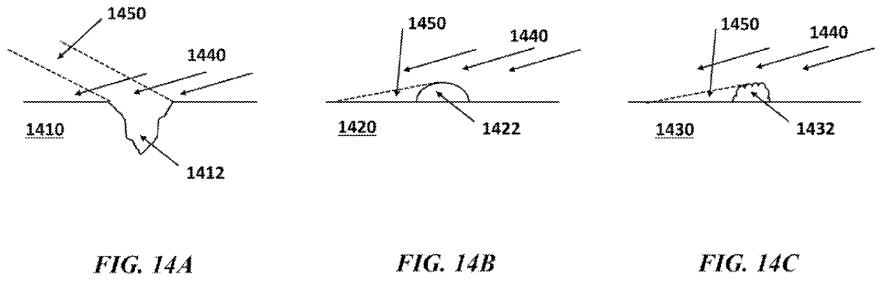

The systems and methods described are useful for the manufacture and/or processing of virtually any material, including any materials produced in sheets. FIGS. 14A-14C show the use of illumination for detection of surface features in non-textile materials. FIG. 14A depicts a metal sheet material 1410 with a surface crack or fissure 1412. An incident beam of light 1440 upon the surface of the metal sheet 1410 produces a shadowed region 1450 that permits detection of the fissure or crack 1412. FIG. 14B depicts a ceramic material 1420 with an adhering particle 1422 attached to its surface. An incident beam of light 1440 upon the surface of the ceramic 1420 produces a shadowed region 1450 that permits detection of the particle 1422. FIG. 14C depicts a polymer material 1430 with a surface contaminant 1432 (e.g., grease from a rotating component) on its surface. An incident beam of light 1440 upon the surface of the polymer 1430 produces a shadowed region 1450 that permits detection of the contaminant 1432.

An illumination module may be configured to be moved or adjusted during a material inspection, quality assurance or defect detection method. An illumination module may be moved or adjusted to alter the direction of the illumination module (e.g., relative to the surface of a material) or change the spacing or gap between the illumination module and a material surface. The illumination module may be manually adjustable or adjusted by a controller or other device (e.g., a computer system). The ability to adjust position and/or orientation may allow the illumination to be optimally targeted at the material sheet. It can also reveal nuances of the surface texture as the light sweeps across the surface at different angles and from different positions, or as the material moves through an illumination area or target region.

### Illumination Module Systems

The present disclosure describes illumination modules that may be utilized to provide illumination for material inspection, quality assurance or defect detection during manufacturing processes. The illumination module may be an inline component that provides illumination onto a moving material surface during a material manufacturing process or a subsequent processing step. Illumination modules may be configured in any appropriate configuration as is best to suit the intended mode of operation and the particular material being characterized. In general, illumination modules, as described herein, may comprise a light-emitting element, a mechanical structure, an electrical system, and optionally, an optical element. The mechanical structure may be utilized for various purposes, including providing support and permitting assembly of the other components of the system, and permitting coupling of the illumination module to other systems, such as manufacturing equipment or light sensors. The electrical system may provide electrical connectivity to the light-emitting element of the illumination module, supply electrical energy to the light-emitting element, and/or integrate the light-emitting element with a computer system that may control the output of the light-emitting element. The optical element may include any optical device that is intended to shape, scale, or direct the emitted light beam, including lenses, filters, and shutters, and shades.

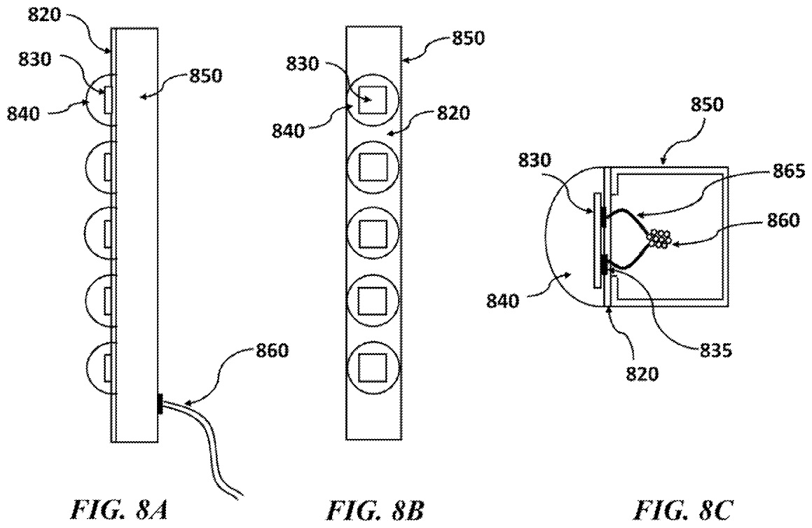

FIGS. 8A-8C depict an exemplary embodiment of an illumination module. FIG. 8A shows the illumination module in a side view with the light-emitting elements 830 directed to the left. Light-emitting elements 830 are coupled to a light assembly board 820 that provides both mechanical support and electrical connectivity to the light emitting elements 820. The light assembly board 820 is coupled to a housing 850 through which electrical wiring 860 is routed. Each light-emitting element 830 is also coupled to an optical element 840 that surrounds the light-emitting element 830. FIG. 8B shows a face-on view of the illumination module with the light-emitting elements 820 directed toward the viewer. FIG. 8C shows a close-up view (scaled differently than FIGS. 8A and 8B) of a cross-section of the illumination module to permit viewing of other details of illumination module structure. The light assembly board 820 is coupled to the hollow housing 850. Electrical wiring 860 is routed through the hollow space in the housing 850, with appropriate wires 865 terminated at particular terminals on the light assembly board 820. The light-emitting elements 830 contact the light assembly board 820 via electrical contacts 835 such that an electrical connection is formed between the light-emitting element 830, the electrical contacts 835, terminals on the light assembly board 820, and electrical wires 865. The light-emitting element is also coupled to the optical element 840 such that the optical element 840 contacts the surface of the light-emitting element.

An illumination module may contain one or more light-emitting elements. A light-emitting element may comprise any source capable of producing light photons within the electromagnetic spectrum, including gamma-rays, x-rays, ultraviolet (UV) light, visible light, infrared (IR) light, microwaves, and radio waves. Light-emitting sources may include any method of producing light, including light-emitting diodes (LED), electrical dissipation, fluorescence, phosphorescence, spontaneous emission, stimulated emission, chemical reaction, and photoelectric emission. Light sources may include LEDs, light bulbs, fluorescent light bulbs, and glow tubes. Light-emitting elements may be permanent fixtures or may be removable or replaceable. In some cases, a light-emitting element may comprise a light chip (e.g., an LED chip). A light-emitting element may generate light at a particular wavelength (e.g., a laser). A light-emitting element may generate light over a particular range of the electromagnetic spectrum (e.g., visible light). A light-emitting element may generate light of more than one types (e.g., visible and IR, UV and visible). A light-emitting element may generate light in a spectrum whose photon number density as a function of wavelength is determined by a characteristic temperature. A light-emitting element may emit a spectrum of light with a characteristic temperature of about 500 K, 750 K, 1000 K, 1250 K, 1500 K, 1750 K, 2000 K, 2250 K, 2500 K, 2750 K, 3000 K, 3250 K, 3500 K, 3750 K, 4000 K, 4250 K, 4500 K, 4750 K, 5000 K, 5250 K, 5500 K, 5750 K, 6000 K, 7000 K, 8000 K, 9000 K, 10000 K, or more than 10000 K. A light-emitting element may emit a spectrum of light with a characteristic temperature of at least about 500 K, 750 K, 1000 K, 1250 K, 1500 K, 1750 K, 2000 K, 2250 K, 2500 K, 2750 K, 3000 K, 3250 K, 3500 K, 3750 K, 4000 K, 4250 K, 4500 K, 4750 K, 5000 K, 5250 K, 5500 K, 5750 K, 6000 K, 7000 K, 8000 K, 9000 K, 10000 K, or more than 10000 K. A light-emitting element may emit a spectrum of light with a characteristic temperature of about 10000 K, 9000 K, 8000K, 7000 K, 6000 K, 5750 K, 5500 K, 5250 K, 5000 K, 4750 K, 4500 K, 4250 K, 4000 K, 3750 K, 3500 K, 3250 K, 3000 K, 2750 K, 2500 K, 2250 K, 2000 K, 1750 K, 1500 K, 1250 K, 1000 K, 750 K, 500 K, or less than 500 K.

An illumination module may comprise more than one light-emitting element. An illumination module may comprise an array of light-emitting elements. The array of light-emitting elements may be arranged in any conceivable fashion, for example in a linear, circular, oval, rectangular, square, diagonal, or diamond pattern. An illumination module may comprise homogeneous light-emitting elements (e.g., each element is configured to produce the same types of light as all other light-emitting elements). An illumination module may comprise a mixture of light-emitting elements, with differing light-emitting elements distinguished by the type of light emitted (e.g., UV vs. visible, 450 nm vs. 700 nm, etc.). An illumination module may comprise an array of light-emitting elements where each element is capable of generating more than one type of light (e.g., an LED chip that can emit UV, visible, and infrared light).

An illumination module may comprise more than one light-emitting element. An illumination module may comprise at least about 2, 5, 10, 15, 20, 25, 30, 35, 40, 45, 50, 55, 60, 65, 70, 75, 80, 85, 90, 95, 100, or more than 100 light-emitting elements. An illumination module may comprise no more than about 100, 95, 90, 85, 80, 75, 70, 65, 60, 55, 50, 45, 40, 45, 40, 35, 30, 25, 20, 15, 10, 5 or less than 5 light-emitting elements. An illumination module may comprise a particular number of light-emitting elements per unit length (e.g., cm, m, in, ft, etc.) or unit area (e.g., cm², m², in², ft², etc.). An illumination module may comprise at least about 1, 5, 10, 20, 25, 50, 75, 100, 150, 200, 250, 500, 1000, or more than 1000 light-emitting elements per unit length or per unit area. An illumination module may comprise no more than about 1000, 500, 250, 200, 150, 100, 75, 50, 25, 20, 10, 5, 1, or more than 1 light-emitting element per unit length or per unit area.

Multiple light-emitting elements may be patterned or positioned on an illumination module to produce a desired light output characteristic. For example, light-emitting elements may be spaced at a sufficient distance from neighboring light-emitting elements to create regions of higher light intensity and regions of lower light intensity when the illumination module is projected onto a surface. Alternatively, light-emitting elements may be positioned within sufficient proximity to create a uniform or substantially uniform light intensity distribution (e.g., varying by no more than 1%, 5%, or 10% from the average light intensity value). Light-emitting elements may be placed in a patterned configuration, such as along a linear or longitudinal axis, or staggered relative to a longitudinal axis. An illumination module may comprise multiple stacked groupings of light-emitting elements (e.g., multiple columns or rows of light-emitting elements). Light-emitting elements may be mounted at uniform pitch or angle within the illumination module structure (i.e., all elements emit light in the same direction) or may be mounted at differing pitch or angle.

The light-emitting element may be associated with one or more optical components. Optical components may direct, scale, or organize a light beam produced by the light-emitting element. Optical components may include lenses, filters, and mirrors. Light from a light-emitting element may be passed through more than one optical component before exiting the illumination, e.g., a series of lenses—collimating, focusing, etc. Optical components may be coupled to a light-emitting element such that all emitted light must pass through the optical component. An optical component may be directly contacted to a surface of a light-emitting element. An optical component may be directly contacted to the light-emitting surface of a light-emitting element. In some cases, an optical component may not physically contact the light-emitting element such that a gap exists between the light-emitting element and the optical component. Optical components may include any conceivable material, including glass, polymers, reflective coatings, minerals, dopants, and fiberoptic materials. In some cases, an optical component may be a moldable composition that can be molded or shaped over the light-emitting element. In some cases, the moldable composition may comprise a thermoplastic material or glass. In some cases, the thermoplastic material may comprise an acrylic polymer. Optical components may include components that collimate, focus, defocus, filter, polarize, or scatter light. In some cases, an illumination module may contain one or more lenses (e.g., collimating lenses) that are directly contacted to the light-emitting surface of a light-emitting element (e.g., an LED chip). An illumination module may also include optical elements, such as shutters, shades, and baffles, that eliminate the direction of light toward unintended directions. For example, shades above and below an illumination module (such as the light bar depicted in FIGS. 8A-C) may prevent diffuse light from being directed in directions other than the intended direction of the emitted light beam. In some cases, the illumination module may not have any additional shutters, shades, or baffling to prevent diffuse light from being directed toward a target, thereby increasing the amount of background light directed onto the target outside the intended projection area of the light beam.

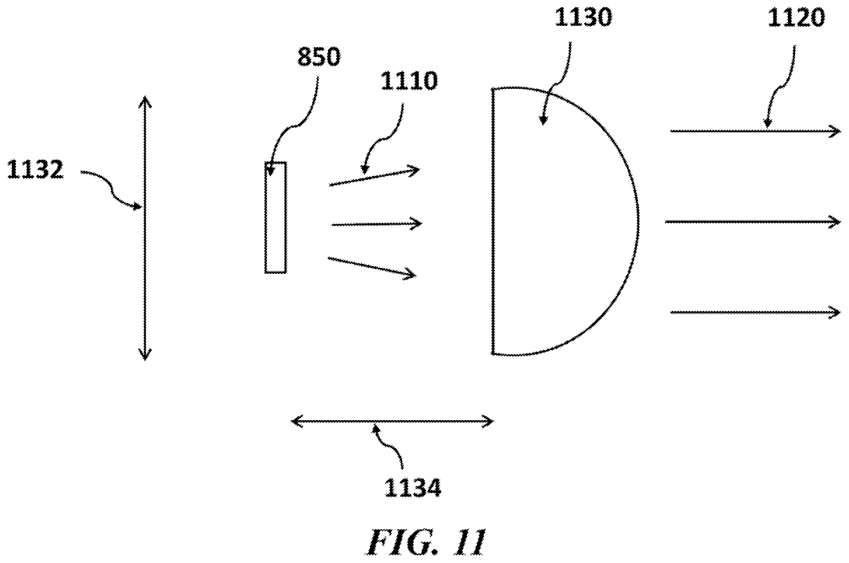

A lens or other optical element may have a particular shape, such as square, rectangular, elliptical, parabolic, polynomial, or hemispherical. A lens or other optical element may be sized to fit over a light-emitting element. FIG. 11 depicts a configuration for a collimating hemispherical collimating lens 1130 (e.g., an acrylic collimating lens) relative to a light-emitting element 850. A non-collimated light beam 1110 passes through the lens 1130 to form a collimated light beam 1120. Based upon the geometry of the light-emitting element, an optical component may have an optimal size 1132 (e.g., width, radius, diameter) and spacing or gap 1134 relative to the light-emitting element 850. A lens or optical element may have a size (e.g., length, radius, diameter) of at least about 1 mm, 2 mm, 3 mm, 4 mm, 5 mm, 6 mm, 7 mm, 8 mm, 9 mm, 1 cm, 2 cm, 3 cm, 4 cm, 5 cm, 10 cm, 20 cm, 25 cm, 50 cm, 1m or more than 1 m. A lens or optical element may have a size (e.g., length, radius, diameter) of no more than about 1 m, 50 cm, 25 cm, 20 cm, 10 cm, 5 cm, 4 cm, 3 cm, 2 cm, 1 cm, 9 mm, 8 mm, 7 mm, 6 mm, 5 mm, 4 mm, 3 mm, 2 mm, 1 mm or less than 1 mm. A lens or other optical component may have a spacing or gap between the surface of a light-emitting element and the portion of the optical component where light first enters the optical component. A lens or optical element may have a spacing or gap separating it from the light-emitting element of at least about 1 mm, 2 mm, 3 mm, 4 mm, 5 mm, 6 mm, 7 mm, 8 mm, 9 mm, 1 cm, 2 cm, 3 cm, 4 cm, 5 cm, 10 cm, 20 cm, 25 cm, 50 cm, 1 m or more than 1 m. A lens or optical element may have a spacing or gap separating it from the light-emitting element of no more than about 1 m, 50 cm, 25 cm, 20 cm, 10 cm, 5 cm, 4 cm, 3 cm, 2 cm, 1 cm, 9 mm, 8 mm, 7 mm, 6 mm, 5 mm, 4 mm, 3 mm, 2 mm, 1 mm or less than 1 mm. The gap may be fixed. In some embodiments, the gap may be adjustable, depending on the type of light-emitting element and/or lens. In some embodiments, the gap can be dynamically adjustable during operation of the illumination module, for example to achieve a variety of different illumination effects/settings. The gap can be adjusted, for example using an actuator operably coupled to the lens and/or the light-emitting element.

An illumination module may comprise one or more light-emitting elements that are physically supported by a mechanical structure. The mechanical structure may include physical structures for securing elements of the illumination module, as well as void space to permit routing paths for electrical elements (e.g., wiring) as well as space for other components such as electrical insulation, heat insulation, batteries and sensors. FIG. 8C depicts a housing structure with a large void space for accommodating additional components. The mechanical structure may also couple to a joining element that holds the light-emitting elements. In some cases, the joining element may be a board to which the light-emitting elements are coupled. In some cases, the joining element may comprise a printed-circuit board (PCB). The printed circuit board may provide electrical connections, electrical terminals, electrical wiring, and/or electrical components that facilitate electrical connectivity to the light-emitting elements.

Mechanical structures may comprise any conceivable construction material, including metals, polymers, ceramics, wood, and other materials. Coupling between elements of the illumination module may be provided by any conceivable fashion including adhesives (glues, epoxies, resins, etc.), fixtures (nails, screws, bolts, rivets, etc.), fittings, and engineered couplings (e.g., snap-together components). The mechanical structure may include additional support elements that secure the illumination module and permit positioning, such as rods, stands, pillars, stanchions, brackets, clamps, arms, stages, levers, wheels, and joists. An illumination module may be capable of coupling to a manufacturing device or associated machinery. An illumination module may be capable of self-support (e.g., free-standing). An illumination module may be coupled to other elements of a detection system, such as sensors and computer systems. The mechanical structure may also include components that permit adjustment of the position and orientation of the illumination module. An illumination module may include components that permit adjustment with up to six degrees of freedom (e.g., x, y, and/or z axis motion). Adjustment devices may include translation stages, hydraulics or pneumatic components, telescoping or rotating components, and any other component capable of altering the position or orientation of the illumination module.

In some cases, an illumination module may also comprise electrical components. In some embodiments, the illumination module comprises electrically-actuated light-emitting elements. The light-emitting elements will be integrated into circuits with an electrical source (e.g., a power outlet, a battery). Electrical connectivity between the light emitting element and an electrical source can be achieved by any available means, such as wiring, printed circuit boards, electrical terminals, electrical pins, and electrical connectors. Illumination modules may also comprise additional electrical components such as resistors, capacitors, voltage transformers, switches, and relays. In some cases, light-emitting elements can comprise electrical connectors that permit coupling to a printed circuit board. The printed circuit board comprises conductive paths that relay electricity from a source to the light-emitting elements. A printed circuit board may further comprise a computer processor that receives wired or wireless communications that permit control of the illumination module. An illumination module may contain external wiring and plugs that permit the module to be connected to a power supply via an outlet or receptacle. An illumination module may comprise one or more batteries that permit operation in the absence of an external power source.

An illumination module may be coupled to an external or internal computer system. The computer system may provide signaling to the illumination module to control operation of the module. The computer system may permit control of output, including on/off control, power outputs, light wavelength control, and direction and distance control between the module and the target material. Computer systems for integration with a computer module are described in greater detail below.

An illumination module may have an expected or characterized duty cycle. A duty cycle may be defined as the number of cycles (e.g., on/off, high power/low power) that the illumination module may undergo before the module performance drops below a threshold value (e.g., power output less than 99%, 95%, 90%, 75%, 50%, 25%, or less of the original output). An illumination module may have a duty cycle of at least about 1000 cycles, 10000 cycles, 100000 cycles, 1000000 cycles, 10000000 cycles, 100000000 cycles, 1000000000 cycles, or more than 1000000000 cycles. An illumination module may have a duty cycle of no more than about 1000000000 cycles, 100000000 cycles, 10000000 cycles, 1000000 cycles, 100000 cycles, 10000 cycles, 1000 cycles, or less than 1000 cycles. An illumination may have an expected or characterized lifetime. A lifetime may be defined as the amount of time for which the illumination module may fully powered before the module performance drops below a threshold value (e.g., power output less than 99%, 95%, 90%, 75%, 50%, 25%, or less of the original output). An illumination module may have a lifetime of at least about 10 hours (hrs), 100 hrs, 1000 hrs, 1500 hrs, 2000 hrs, 2500 hrs, 3000 hrs, 3500 hrs, 4000 hrs, 5000 hrs, 10000 hrs, 50000 hrs, 100000 hrs, or more than 100000 hrs. An illumination module may have a lifetime of no more than about 100000 hours (hrs), 50000 hrs, 10000 hrs, 5000 hrs, 4000 hrs, 3500 hrs 3000 hrs, 2500 hrs, 2000 hrs, 1500 hrs, 1000 hrs, 100 hrs, 10 hrs, or less than 10 hrs.

### Additional Embodiments

The illumination systems described herein and the various components of the illumination systems (e.g., the illumination modules or the light sensors) may be used in combination with one or more knitting machines or one or more weaving machines. The one or more knitting machines may comprise, for example, circular knitting machines, flat knitting machines, warp knitting machines, weft knitting machines, straight bar knitting machines, and/or flat bar knitting machines. The one or more weaving machines may comprise, for example, shuttle weaving machines, circular weaving machines, narrow fabric weaving machines, shuttle looms, air jet looms, water jet looms, rapier looms, projectile looms, Jacquard looms, and/or circular looms.

In some cases, the illumination systems described herein and the various components of the illumination systems (e.g., the illumination modules or the light sensors) may be used in combination with one or more material fabrication and processing machines. The material fabrication and processing machines may comprise, for example, textile finishing machines such as inspection machines or stenter machines. As used herein, a stenter machine may comprise a machine for drying and heat treating fabric after wet processing. In some cases, the material fabrication and processing machine may comprise a machine configured to perform a chemical, thermal, or mechanical process to a fabric or web of material. The chemical process may comprise bleaching or mercerizing the fabric or web of material, or applying a film, finish, or polish to the fabric or web of material. In some examples, the finish or polish may comprise a water repellant material, a flame retardant material, an anti-bacterial material, or an insulation material. The thermal process may involve heating or cooling the fabric (e.g., by exposure to a heat source or to a fluid that is capable of facilitating a transfer of thermal energy to or from the fabric or web of material). The mechanical process may comprise, for example, washing, drying, stabilizing, calendaring, fulling, crabbing, napping, or shearing.

The illumination systems described herein may be used in combination with one or more cameras and/or one or more light modules in order to aid in defect detection and quality control. The one or more cameras may be configured to capture one or more images or videos of at least one inspection area that is illuminated using the one or more light modules and/or the illumination systems of the present disclosure. The at least one inspection area may correspond to a surface, a portion, a volume, or a section of a material, a web, a sheet, a fabric, a textile, paper, a woven material, a non-woven material, a metal, a plastic, a composite, or a film. In some embodiments, the illumination systems, the illumination modules, and/or the cameras described herein may be used compatibly with one or more circular knitting machines. In some cases, the illumination modules and/or the cameras disclosed herein may be placed inside a portion of the one or more circular knitting machines. For example, the illumination modules and/or the cameras may be placed inside a fabrics tube of the one or more circular knitting machines. In other cases, the illumination modules and/or the cameras may be placed outside a portion of the one or more circular knitting machines. In some embodiments, the illumination modules and/or the cameras may be placed outside of the fabrics tube of the one or more circular knitting machines. In some cases, a first illumination module and/or camera may be placed inside the one or more circular knitting machines and a second illumination module and/or camera may be placed outside the one or more circular knitting machines. In some cases, a first illumination module and/or camera may be placed inside a fabrics tube of the one or more circular knitting machines and a second illumination module and/or camera may be placed outside the fabrics tube of the one or more circular knitting machines.

In some cases, the illumination modules and/or cameras may be movable relative to one or more portions or components of the one or more circular knitting machines for calibration purposes. One or more movable mechanisms (e.g., stepper motors or servo motors) may be used to adjust a position or an orientation of the illumination modules and/or cameras relative to a material surface that is being fabricated or processed using the one or more circular knitting machines.

As described elsewhere herein, one or more light sensors may be used to detect and receive light that is transmitted by the illumination modules and reflected from a material surface. The light sensors disclosed herein may be used with one or more circular knitting machines. The light sensors may comprise, for example, one or more cameras, imaging units, or imaging sensors. In some cases, the light sensors may be located inside the one or more circular knitting machines. For example, the light sensors may be placed inside a fabrics tube of the one or more circular knitting machines. In other cases, the light sensors may be placed outside a portion of the one or more circular knitting machines. In some embodiments, the light sensors may be placed outside of the fabrics tube of the one or more circular knitting machines. In some cases, a first light sensor may be placed inside the one or more circular knitting machines and a second light sensor may be placed outside the one or more circular knitting machines. In some cases, a first light sensor may be placed inside a fabrics tube of the one or more circular knitting machines and a second light sensor may be placed outside the fabrics tube of the one or more circular knitting machines.

In some cases, the light sensors may be movable relative to one or more portions or components of the one or more circular knitting machines for calibration purposes. One or more movable mechanisms (e.g., stepper motors or servo motors) may be used to adjust a position or an orientation of the light sensors relative to a material surface that is being fabricated or processed using the one or more circular knitting machines.

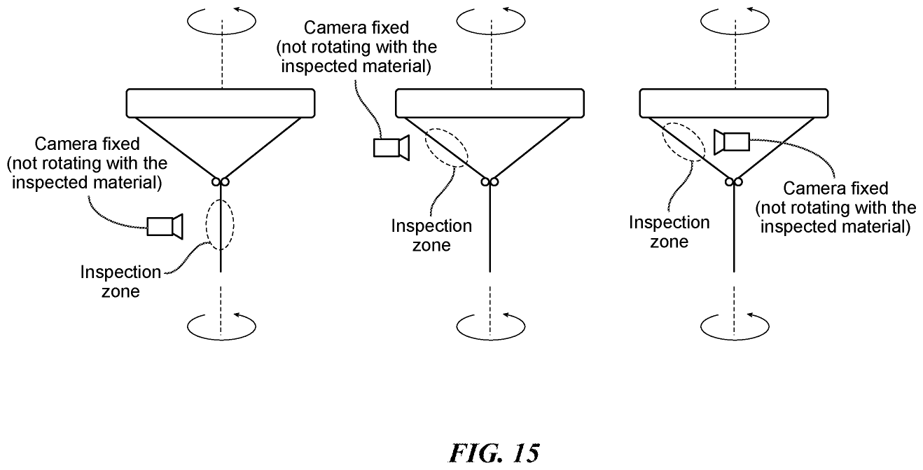

FIG. 15 illustrates an example of an optical detection system for defect detection and quality control. The optical detection system may comprise one or more imaging units with line of sight access to one or more inspection zones. The one or more imaging units may be used to detect defects, perform quality control, and/or perform calibration. The one or more inspection zones may correspond to one or more portions or regions of a material fabrication or processing machine (e.g., a circular knitting machine), or one or more portions or regions of a material that is produced using the material fabrication or processing machine. The one or more imaging units may be located remote from the material fabrication or processing machine. The one or more imaging units may be positioned adjacent to the material fabrication or processing machine. In some cases, the one or more imaging units may be affixed, coupled, or attached to a portion (e.g., a structural component) of the material fabrication or processing machine.

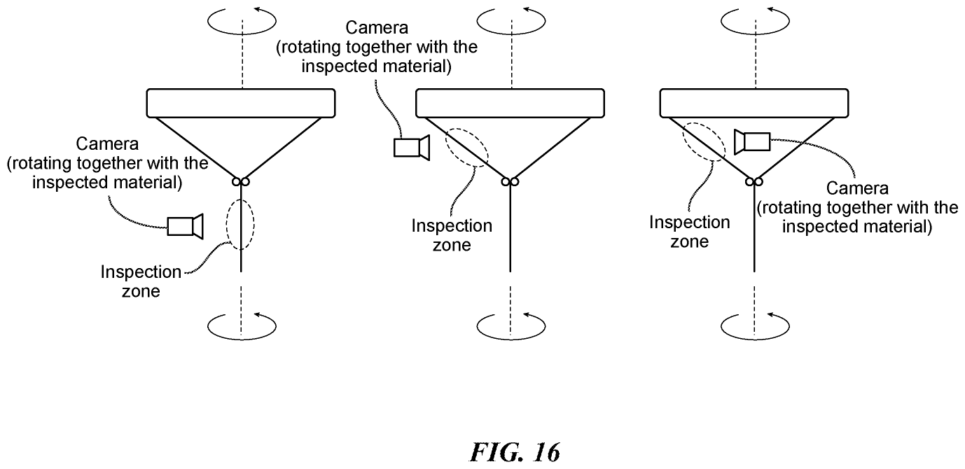

In any of the embodiments described herein, the material fabrication or processing machine may comprise a knitting machine. The knitting machine may comprise, for example, a circular knitting machine. The circular knitting machine may comprise one or more rotatable components. In some cases, at least a portion of the material that is fabricated or processed using the circular knitting machine may rotate relative to the camera. In some embodiments, for example as shown in FIG. 15, the one or more imaging units may be fixed or set in a predetermined position or orientation such that the one or more imaging units do not rotate with the inspected material. In other embodiments, for example as shown in FIG. 16, the one or more imaging units may be configured to move (e.g., rotate and/or translate) relative to the inspected material. In some instances, the one or more imaging units may be configured to rotate together with the inspected material. In some cases, the one or more imaging units may be provided external to or outside of the circular knitting machine. In other cases, the one or more imaging units may be provided inside or within a portion of the circular knitting machine. In some embodiments, a plurality of imaging units and a plurality of illumination modules may be provided. The plurality of imaging units may comprise at least a first imaging unit that is fixed and at least a second imaging unit that is configured to rotate relative to the inspected material. The plurality of illumination modules may comprise at least a first illumination module that is fixed and at least a second illumination module that is configured to rotate relative to the inspected material. In some cases, both the plurality of imaging units and the plurality of illumination modules may be fixed relative to the inspected material. In other cases, both the plurality of imaging units and the plurality of illumination modules may be configured to rotate relative to the inspected material. In some embodiments, at least one imaging unit of the plurality of imaging units may be fixed relative to the inspected material, and at least one illumination module of the plurality of illumination modules may be configured to rotate relative to the inspected material. In other embodiments, at least one imaging unit of the plurality of imaging units may be configured to rotate relative to the inspected material, and at least one illumination module of the plurality of illumination modules may be fixed relative to the inspected material. Alternatively, any one of the imaging units may be fixed or rotatable relative to the inspected material, and any one of the illumination modules may be fixed or rotatable relative to the inspected material.

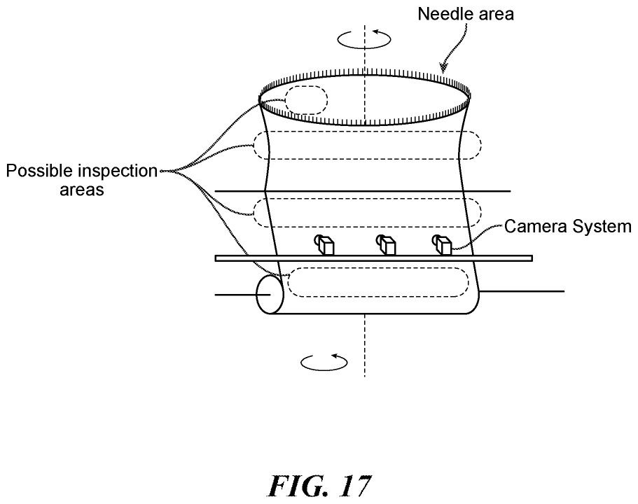

FIG. 17 schematically illustrates various inspection areas that may be monitored using an imaging system. The imaging system may comprise one or more imaging units for detecting defects, performing quality control, and/or calibration. As described above, the one or more imaging units may be fixed and stationary relative to the material fabrication and processing machine or a material that is produced and/or processed using the material fabrication and processing machine. Alternatively, the one or more imaging units may be configured to move (e.g., translate and/or rotate) relative to the material fabrication and processing machine or a material that is produced and/or processed using the material fabrication and processing machine. The various inspection areas may correspond to different portions or regions of a circular knitting machine or different portions or regions of a material that is fabricated or processed using a circular knitting machine. In some cases, the inspection area may correspond to a portion of the material that is adjacent to a needle area of the circular knitting machine. In some cases, the inspection area may correspond to a portion of the material that is below the needle area. In some embodiments, the various inspection areas may correspond to a front portion and/or a back portion of a fabricated material.

Camera Bar and Light Bar

In some cases, the one or more cameras may be provided on or coupled to a structure. The structure may comprise a bar or a beam. The bar or beam may comprise a linear section and/or one or more non-linear sections. In some embodiments, the one or more cameras may be provided in a linear or lateral configuration such two or more of the cameras are aligned along a same plane or axis. In other embodiments, the one or more cameras may be provided in a non-linear configuration. In some cases, the cameras may be spaced apart at a same distance. In other cases, the cameras may be spaced apart at different distances. The one or more cameras may be angled towards a surface of a material or a web of fabric that is being fabricated or processed using a machine. The machine may comprise a material fabrication and processing machine as described elsewhere herein, or any type of roll-to-roll processing machine. Roll-to-roll processing may comprise a fabrication method used in manufacturing that (i) embeds, coats, prints, or laminates varying applications onto a flexible rolled substrate material or (ii) physically and/or chemically processes or manipulates a flexible rolled substrate material as the substrate material is fed continuously from one roller on to another. The roll-to-roll processing machine may comprise one or more rollers, known as the web path, which winds a substrate material over and through these rollers as it carries out a number of physical and/or chemical operations. The roll-to-roll processing machine may be configured to (i) apply one or more additive or subtractive materials onto the substrate and/or (ii) physically or chemically process or manipulate the substrate as it moves along the web to create or produce a product or part.

In some cases, the one or more illumination modules may be provided on or coupled to a structure. The structure may comprise a bar or a beam. The bar or beam may comprise a linear section and/or one or more non-linear sections. In some embodiments, the one or more illumination modules may be provided in a linear or lateral configuration such two or more of the illumination modules are aligned along a same plane or axis. In other embodiments, the one or more illumination modules may be provided in a non-linear configuration. In some cases, the illumination modules may be spaced apart at a same distance. In other cases, the illumination modules may be spaced apart at different distances. The one or more illumination modules may be angled towards a surface of a material or a web of fabric that is being fabricated or processed using a machine. The machine may comprise a material fabrication and processing machine or any type of roll-to-roll processing machine as described elsewhere herein.

In some cases, the illumination modules may be provided as part of a light bar. The light bar may be configured to position and/or orient the illumination modules such that the illumination modules are capable of providing low angle light or illumination to the material surface. As used herein, low angle light or low angle illumination may refer to an angle at which light emitted from the illumination modules strikes a surface of the material. In some cases, the angle may be quantified as or associated with an angle of incidence of the light on the material surface. In some cases, the angle at which the light emitted from the illumination modules strikes a surface of the material may be at least about 0.1 degrees, 1 degree, 2 degrees, 3 degrees, 4 degrees, 5 degrees, 6 degrees, 7 degrees, 8 degrees, 9 degrees, 10 degrees, 15 degrees, 20 degrees, 25 degrees, 30 degrees, 35 degrees, 40 degrees, 45 degrees, 50 degrees, 55 degrees, 60 degrees, 65 degrees, 70 degrees, 75 degrees, 80 degrees, 85 degrees, 90 degrees, or more. In some cases, the angle at which the light emitted from the illumination modules strikes a surface of the material may be at most about 90 degrees, 85 degrees, 80 degrees, 75 degrees, 70 degrees, 65 degrees, 60 degrees, 55 degrees, 50 degrees, 45 degrees, 40 degrees, 35 degrees, 30 degrees, 25 degrees, 20 degrees, 15 degrees, 10 degrees, 9 degrees, 8 degrees, 7 degrees, 6 degrees, 5 degrees, 4 degrees, 3 degrees, 2 degrees, 1 degree, 0.1 degrees, or less. Low angle light or low angle illumination may permit the detection of certain defects or quality issues with the material that may not be easily observable or detectable using, for example, light that is normal, orthogonal, or perpendicular to the surface of the material surface.

In some cases, the cameras and illumination modules described herein may be used compatibly with any type of roll-to-roll processing machine. For example, the illumination modules described herein may be used to provide low angle light or low angle illumination to a material or product that is being generated or processed using a roll-to-roll processing machine. The material or product may comprise, for example, a web, a surface material, a sheet, a fabric, a textile, paper, a woven material, a non-woven material, a metal, a plastic, a composite, or a film. The cameras described herein may be positioned, oriented, and configured to receive the low angle light that is transmitted to the material or product and reflected from a surface or a portion of the material or product. The cameras may be configured to obtain one or more images or videos of the material or product (or a surface of the material or product) based on the low angle light reflected from the material or product. In some cases, the system may further comprise an image processing unit configured to use the one or more images or videos to detect one or more defects in the material or product, or to perform quality control for the material or product. Such quality control may be performed as the material or product is being fabricated or processed, or after the fabrication or processing of the material or product. As described above, the roll-to-roll processing machine may comprise a machine configured for roll-to-roll processing. Roll-to-roll processing may comprise a fabrication method used in manufacturing that (i) embeds, coats, prints, or laminates varying applications onto a flexible rolled substrate material or (ii) physically and/or chemically processes or manipulates a flexible rolled substrate material as the substrate material is fed continuously from one roller on to another. The roll-to-roll processing machine may comprise one or more rollers, known as the web path, which winds a substrate material over and through these rollers as it carries out a number of physical and/or chemical operations. The roll-to-roll processing machine may be configured to (i) apply one or more additive or subtractive materials onto the substrate and/or (ii) physically or chemically process or manipulate the substrate as it moves along the web to create or produce a product or part.

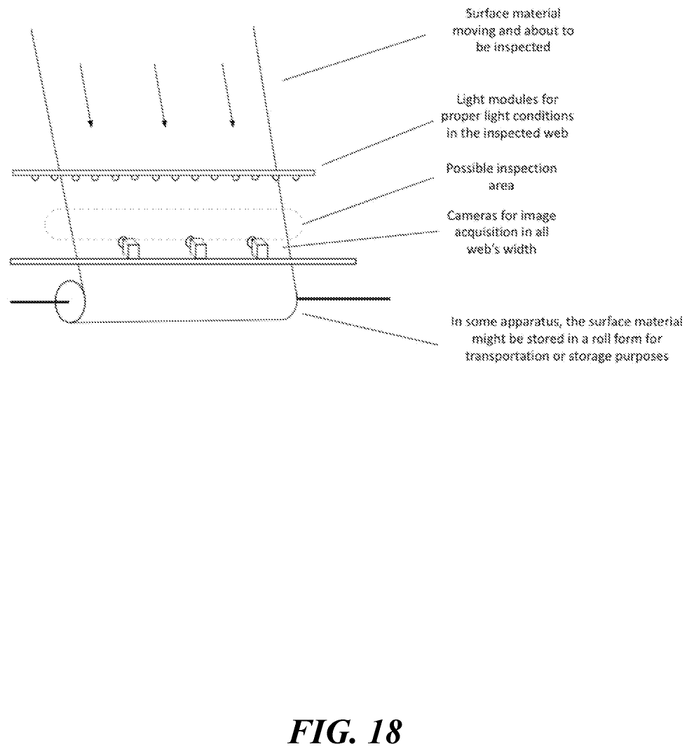

FIGS. 18, 19, 20, and 21 schematically illustrate an illumination system comprising a light bar and a camera bar. The light bar may comprise one or more illumination modules that are configured to provide illumination to a possible inspection area as a surface material is moving. The illumination modules may provide the proper lighting conditions needed to inspect the material or web. In some cases, the proper lighting conditions may be produced when the one or more illumination modules are positioned and oriented to provide low angle light or illumination to one or more inspection areas on the surface of the material or web. In some cases, a camera bar comprising one or more cameras may be used to capture images or videos of the portion of the material or web corresponding to and/or within the inspection area. The cameras and/or the camera bar may span a length or a width of the material or web or a portion thereof.

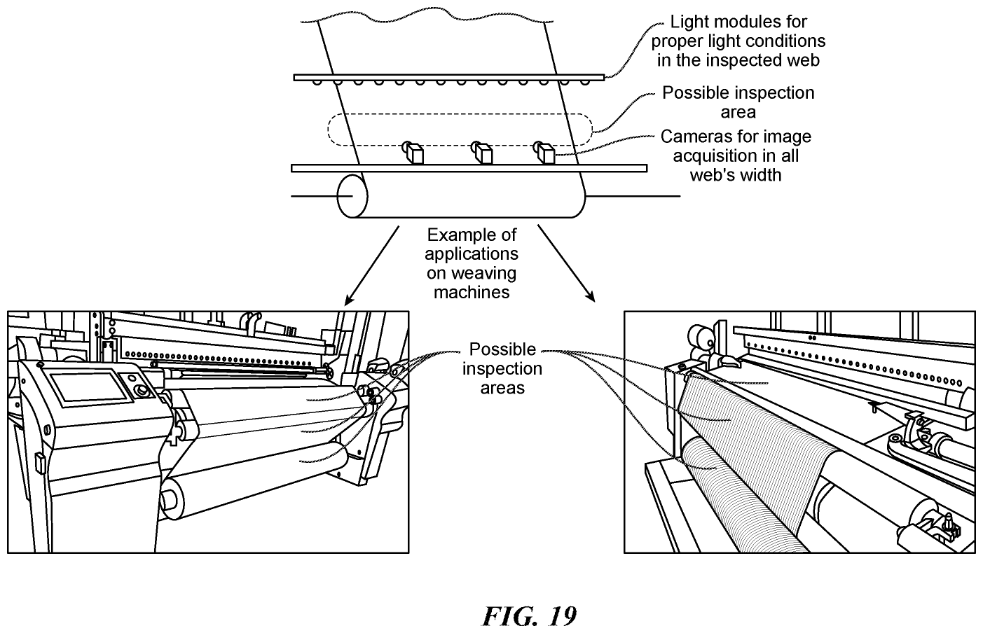

As shown in FIG. 19, the inspection areas may correspond to several portions or sections of a material or web that is being fabricated or processed by a material fabrication and processing machine or a roll-to-roll processing machine. The material fabrication and processing machine may be, for example, any type of weaving machine as described elsewhere herein. In some cases, the inspection areas may correspond to a portion of a material or a web that is adjacent to one or more rollers. In other cases, the inspection areas may correspond to a portion of a material or a web that is between two or more rollers. The inspection areas may be on different planes in three-dimensional space relative to each other. In some cases, the different planes may comprise parallel planes. In other cases, the different planes may comprise non-parallel planes that intersect each other at an angle. In some cases, the surface material may be provided or stored in a roll form for transportation or storage purposes. In such cases, the inspection areas may comprise a curved surface of the surface material in a roll form.

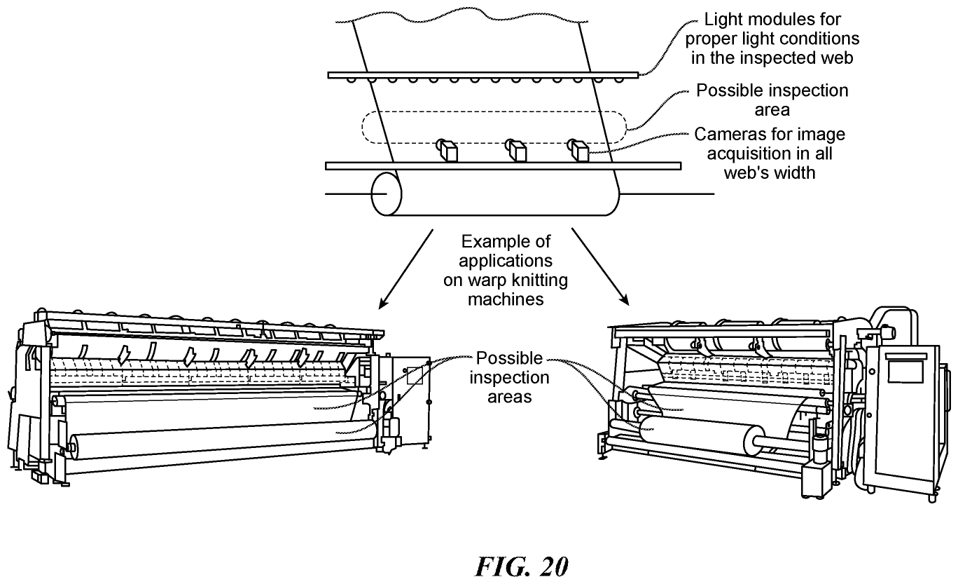

FIG. 20 schematically illustrates an example of an illumination system that is compatible with various types of warp knitting machines. The system may comprise a camera bar and a light bar as described elsewhere herein. The camera bar and the light bar may be used to facilitate inspection of various areas on a material surface or web for defect detection and/or quality control purposes. In some cases, the inspection areas may correspond to a portion of a material or a web that is adjacent to one or more rollers. In other cases, the inspection areas may correspond to a portion of a material or a web that is between two or more rollers. The inspection areas may be on different planes in three-dimensional space relative to each other. In some cases, the different planes may comprise parallel planes. In other cases, the different planes may comprise non-parallel planes that intersect each other at an angle. The material or web may be inspected in different regions as the material or web is being fabricated or processed using the warp knitting machines.

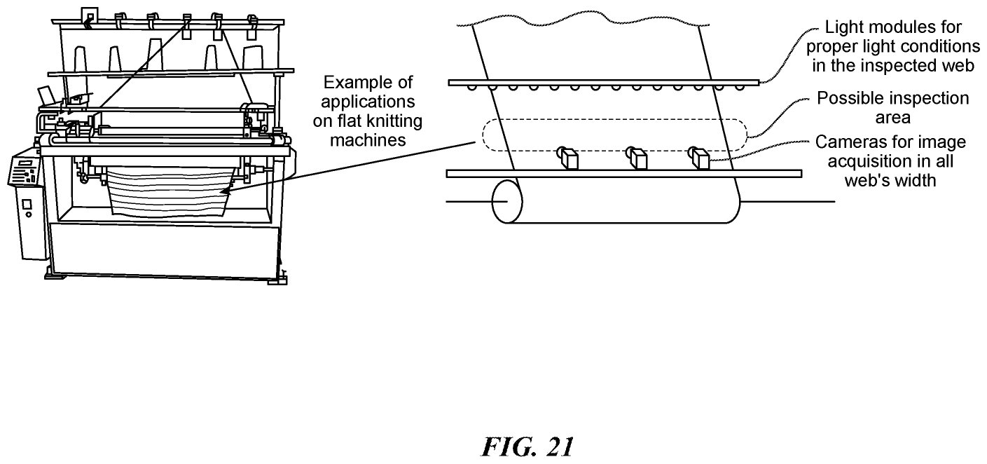

FIG. 21 schematically illustrates an example of an illumination system that is compatible with various types of flat knitting machines. The system may comprise a camera bar and a light bar as described elsewhere herein. The camera bar and the light bar may be used to facilitate inspection of various areas on a material surface or web for defect detection and/or quality control purposes. In some cases, the inspection areas may correspond to a portion of a material or a web that is adjacent to one or more rollers. In other cases, the inspection areas may correspond to a portion of a material or a web that is between two or more rollers. Alternatively, the inspection areas may correspond to a portion of a material or a web that is suspended from a roller of the flat knitting machine. The inspection areas may be on different planes in three-dimensional space relative to each other. In some cases, the different planes may comprise parallel planes. In other cases, the different planes may comprise non-parallel planes that intersect each other at an angle. The material or web may be inspected in different regions as the material or web is being fabricated or processed using the flat knitting machine.

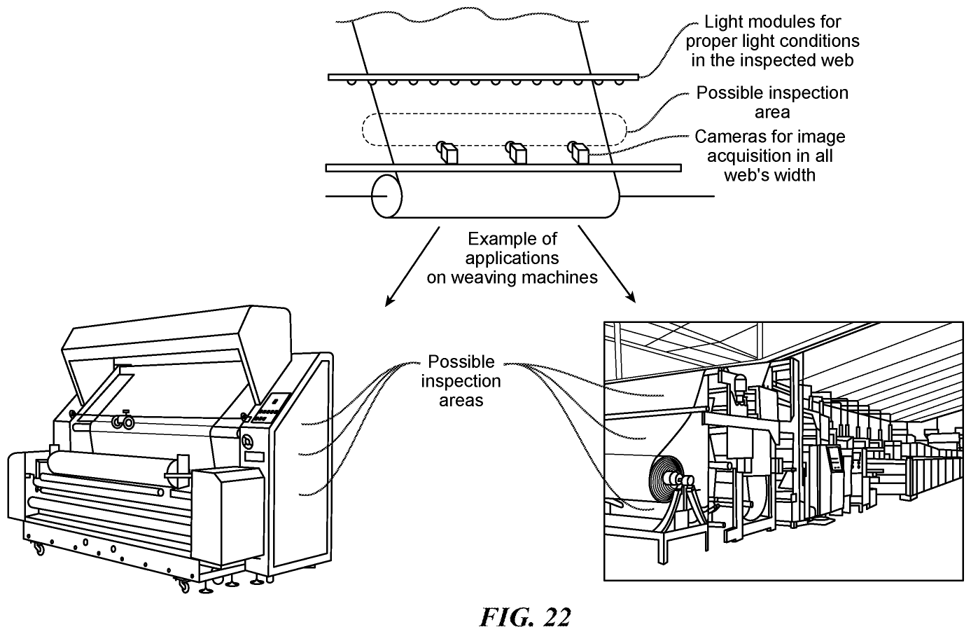

FIG. 22 schematically illustrates an example of an illumination system that is compatible with various types of machines. The various types of machines may comprise any type of machine that is configured to physically or chemically process a material. The machine may comprise, for example, a roll-to-roll processing machine. Roll-to-roll processing may comprise a fabrication method used in manufacturing that (i) embeds, coats, prints, or laminates varying applications onto a flexible rolled substrate material or (ii) physically and/or chemically processes or manipulates a flexible rolled substrate material as the substrate material is fed continuously from one roller on to another. The roll-to-roll processing machine may comprise one or more rollers, known as the web path, which winds a substrate material over and through these rollers as it carries out a number of physical and/or chemical operations. The roll-to-roll processing machine may be configured to (i) apply one or more additive or subtractive materials onto the substrate and/or (ii) physically or chemically process or manipulate the substrate as it moves along the web to create or produce a product or part.

In some cases, a plurality of different areas or portions of a material or a web may be inspected using one or more cameras and one or more illumination modules. In some cases, a first set of cameras and a first set of illumination modules may be used to inspect a first inspection area, and a second set of cameras and a second set of illumination modules may be used to inspect a second inspection area. In some cases, one set of cameras and one set of illumination modules may be used to inspect one or more inspection regions. In such cases, the set of cameras and the set of illumination modules may be configured to change their positions and/or orientations relative to the various inspection areas to provide an optimal lighting or illumination angle and/or an optimal image or video capture angle. The optimal light or illumination angle may be, for example, a low angle light or a low angle illumination. In some cases, one or more motors may be used to adjust a position and/or an orientation of the cameras and/or illumination modules relative to the material surface or web to inspect different inspection areas for defect detection and quality control.

Calibration

In any of the embodiments described herein, calibration may be performed by obtaining one or more images of a material surface and optimizing one or more imaging parameters of the cameras, based on software processing of the one or more images, to achieve an optimal spatial resolution. The imaging parameters may comprise, for example, an exposure time, a shutter speed, an aperture, a film speed, a field of view, an area of focus, a focus distance, a capture rate, or a capture time associated with the cameras.

In some cases, the cameras described herein may be calibrated using one or more images of the material surface, which material surface may comprise one or more calibration features. In some cases, the systems of the present disclosure may be configured to implement an algorithm to optimize one or more operational parameters (e.g., imaging parameters) of the cameras for an optimal spatial resolution or imaging performance. The algorithm may comprise, for example, an artificial intelligence or machine learning based algorithm. The one or more artificial intelligence or machine learning based algorithms can be used to implement adaptive control of the calibration system (or one or more components or subsystems of the illumination systems disclosed herein or any defect detection and quality control systems comprising the illumination systems of the present disclosure) based on one or more images of the material surface or the one or more calibration features provided on the material surface. The artificial intelligence or machine learning based algorithm may be, for example, an unsupervised learning algorithm, a supervised learning algorithm, or a combination thereof. In some embodiments, the artificial intelligence or machine learning based algorithm may comprise a neural network (e.g., a deep neural network (DNN)). In some embodiments, the deep neural network may comprise a convolutional neural network (CNN). The CNN may comprise, for example, U-Net, ImageNet, LeNet-5, AlexNet, ZFNet, GoogleNet, VGGNet, ResNet18, or ResNet, etc. In some cases, the neural network may be, for example, a deep feed forward neural network, a recurrent neural network (RNN), LSTM (Long Short Term Memory), GRU (Gated Recurrent Unit), an autoencoder, a variational autoencoder, an adversarial autoencoder, a denoising autoencoder, a sparse autoencoder, a Boltzmann machine (BM), a restricted Boltzmann machine (RBM or Restricted BM), a deep belief network, a generative adversarial network (GAN), a deep residual network, a capsule network, or an attention/transformer networks. In some embodiments, the neural network may comprise one or more neural network layers. In some instances, the neural network may have at least about 2 to 1000 or more neural network layers. In some cases, the artificial intelligence or machine learning based algorithm may be configured to implement, for example, a random forest, a boosted decision tree, a classification tree, a regression tree, a bagging tree, a neural network, or a rotation forest.

In some cases, the one or more cameras or imaging sensors may be provided inside a fabrics tube of a circular knitting machine. In other cases, the one or more cameras or imaging sensors may be provided outside of a fabrics tube of a circular knitting machine. In some cases, the one or more illumination modules may be provided inside a fabrics tube of a circular knitting machine. In other cases, the one or more illumination modules may be provided outside of a fabrics tube of a circular knitting machine.

In some embodiments, the one or more cameras or imaging sensors may be fixed to a rotational structure or component of the circular knitting machine. The one or more cameras or imaging sensors may be used to acquire images and/or videos of a manufactured material as the rotational structure or component is moving (e.g., rotating) relative to a material surface. The one or more cameras or imaging sensors may be used to acquire images and/or videos of a manufactured material as the one or more cameras or imaging sensors are moving (e.g., rotating) relative to a material surface. In some cases, the one or more cameras or imaging sensors may be fixed to the circular knitting machine (e.g., fixed to a structural component of the circular knitting machine) and configured to capture images and/or videos of the manufactured web as the web is rotating. In some cases, the one or more cameras or imaging sensors may be fixed to the circular knitting machine and configured to capture images and/or videos of the web from inside a tubular portion of the circular knitting machine. In some cases, the one or more cameras or imaging sensors may be fixed to a rotational structure of the circular knitting machine and configured to acquire images and/or videos of the manufactured web from inside a tubular portion of the circular knitting machine.

In some embodiments, the one or more illumination modules may be fixed to a rotational structure or component of the circular knitting machine. The one or more illumination modules may be used to illuminate a portion of a surface material or web as the rotational structure or component is moving (e.g., rotating) relative to the material surface. The one or more illumination modules may be used to illuminate a portion of a surface material or web as the one or more illumination modules are moving (e.g., rotating) relative to a material surface. In some cases, the one or more illumination modules may be fixed to the circular knitting machine (e.g., fixed to a structural component of the circular knitting machine) and configured to illuminate one or more inspection areas of the manufactured web as the web is rotating. In some cases, the one or more illumination modules may be fixed to the circular knitting machine and configured to illuminate one or more inspection areas of the web from inside a tubular portion of the circular knitting machine. In some cases, the one or more illumination modules may be fixed to a rotational structure of the circular knitting machine and configured to illuminate one or more inspection areas of the manufactured web from inside a tubular portion of the circular knitting machine.

The illumination systems of the present disclosure may be used in conjunction with one or more cameras. The one or more cameras and/or illumination modules may be positioned adjacent to or in close proximity to the material fabrication and processing machine. The one or more cameras or illumination modules may be external to the material fabrication and processing machine. The one or more cameras or illumination modules may be provided inside a circular knitting machine. As used herein, “inside a circular knitting machine” may refer to a placement of the one or more cameras or illumination modules within a perimeter or physical footprint of the circular knitting machine. In some cases, “inside a circular knitting machine” may refer to a placement of the one or more cameras or illumination modules near one or more internal regions, edges, or components of the circular knitting machine.

In some cases, one or more lighting parameters associated with the illumination modules may be adjusted for optimal lighting of various inspection areas. The one or more lighting parameters may comprise, for example, a position and/or an orientation of one or more illumination modules relative to (i) the material surface or (ii) one or more cameras.

In some embodiments, a calibration unit may be configured to process one or more images captured by the cameras to adjust one or more operational parameters of the illumination modules. The one or more operational parameters may comprise an intensity, a color, a brightness, a temperature, a wavelength, a frequency, a pulse width, a pulse frequency, or any other parameter that controls a transmission of light/electromagnetic waves or a physical characteristic of light/electromagnetic waves.

In some embodiments, the calibration unit may be configured to optimize or calibrate the one or more cameras and/or the one or more illumination modules based on the images captured using the cameras. Such optimization or calibration may comprise, for example, adjusting a focus, an aperture, and/or an exposure time of the one or more cameras or imaging units. In some cases, the optimization or calibration may comprise a calibration of a position and/or orientation of one or more illumination modules, or an operational parameter of the one or more illumination modules. In some cases, the one or more illumination modules may be used to generate optical projections of one or more calibration features. The operational parameter of the one or more illumination modules may comprise, for example, an intensity, a color, a brightness, a temperature, a wavelength, a frequency, a pulse width, a pulse frequency, or any other parameter that controls a transmission of light/electromagnetic waves or a physical characteristic of light/electromagnetic waves.

In some embodiments, calibration may comprise one or more dynamic calibration methods that can be implemented in real-time during a production or a processing of a textile material, a fabric, or a web using a material fabrication and processing machine. For example, the calibration methods may be used to dynamically optimize one or more image resolution metrics by adjusting one or more operational parameters of an illumination module or a camera (e.g., light intensity, exposure time, position of the light source, orientation of the light source, etc.) as the textile material or web is being fabricated or processed.

### Computer Systems

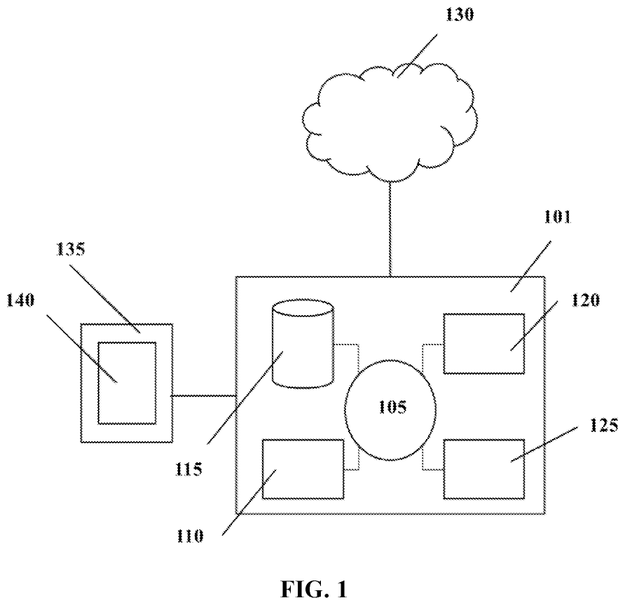

The present disclosure provides computer systems that are programmed to implement methods of the disclosure. FIG. 1 shows a computer control system 101 that is programmed or otherwise configured to control an illumination module. The computer control system 101 can regulate various aspects of the methods of the present disclosure, such as, for example, methods of controlling the power density output of an illumination module. The computer control system 101 can be implemented on an electronic device of a user or a computer system that is remotely located with respect to the electronic device. The electronic device can be a mobile electronic device.

The computer system 101 includes a central processing unit (CPU, also “processor” and “computer processor” herein) 105, which can be a single core or multi core processor, or a plurality of processors for parallel processing. The computer control system 101 also includes memory or memory location 110 (e.g., random-access memory, read-only memory, flash memory), electronic storage unit 115 (e.g., hard disk), communication interface 120 (e.g., network adapter) for communicating with one or more other systems, and peripheral devices 125, such as cache, other memory, data storage and/or electronic display adapters. The memory 110, storage unit 115, interface 120 and peripheral devices 125 are in communication with the CPU 105 through a communication bus (solid lines), such as a motherboard. The storage unit 115 can be a data storage unit (or data repository) for storing data. The computer control system 101 can be operatively coupled to a computer network (“network”) 130 with the aid of the communication interface 120. The network 130 can be the Internet, an internet and/or extranet, or an intranet and/or extranet that is in communication with the Internet. The network 130 in some cases is a telecommunication and/or data network. The network 130 can include one or more computer servers, which can enable distributed computing, such as cloud computing. The network 130, in some cases with the aid of the computer system 101, can implement a peer-to-peer network, which may enable devices coupled to the computer system 101 to behave as a client or a server.

In some cases, the computer system 101 may comprise a graphics processor unit (GPU) 102 and/or a user interface (UI) 103 and/or an actuator 104. The computer system 101 may comprise an external or internal GPU 102. In some cases, a system may comprise more than one computer system 101 or subcomponent of a computer system. A system with multiple computer systems 101 or multiple GPUs 102 may be arranged in a parallel or series architecture. Computer systems 101 or GPUs 102 may be arranged to increase or optimize the computational power of a system for an intended application. In some cases, one or more computer systems 101 may send or receive data from an external device (e.g., an illumination module).

The CPU 105 can execute a sequence of machine-readable instructions, which can be embodied in a program or software. The instructions may be stored in a memory location, such as the memory 110. The instructions can be directed to the CPU 105, which can subsequently program or otherwise configure the CPU 105 to implement methods of the present disclosure. Examples of operations performed by the CPU 105 can include fetch, decode, execute, and writeback.

The CPU 105 can be part of a circuit, such as an integrated circuit. One or more other components of the system 101 can be included in the circuit. In some cases, the circuit is an application specific integrated circuit (ASIC).

The storage unit 115 can store files, such as drivers, libraries and saved programs. The storage unit 115 can store user data, e.g., user preferences and user programs. The computer system 101 in some cases can include one or more additional data storage units that are external to the computer system 101, such as located on a remote server that is in communication with the computer system 101 through an intranet or the Internet.

The computer system 101 can communicate with one or more remote computer systems through the network 130. For instance, the computer system 101 can communicate with a remote computer system of a user (e.g., a user controlling the manufacture of a material or product). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 101 via the network 130.

Methods as described herein can be implemented by way of machine (e.g., computer processor) executable code stored on an electronic storage location of the computer system 101, such as, for example, on the memory 110 or electronic storage unit 115. The machine executable or machine readable code can be provided in the form of software. During use, the code can be executed by the processor 105. In some cases, the code can be retrieved from the storage unit 115 and stored on the memory 110 for ready access by the processor 105. In some situations, the electronic storage unit 115 can be precluded, and machine-executable instructions are stored on memory 110.

The code can be pre-compiled and configured for use with a machine having a processer adapted to execute the code, or can be compiled during runtime. The code can be supplied in a programming language that can be selected to enable the code to execute in a pre-compiled or as-compiled fashion.

Aspects of the systems and methods provided herein, such as the computer system 401, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 101 can include or be in communication with an electronic display 135 that comprises a user interface (UI) 140 for providing, for example, the display of control parameters for an illumination module. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 105. The algorithm can, for example, collect user inputs for control of an illumination module and relay the inputs to the illumination module to alter the output of the module during a quality assurance or defect detection method.

### EXAMPLES

### Example 1—LED Chip Illumination Module

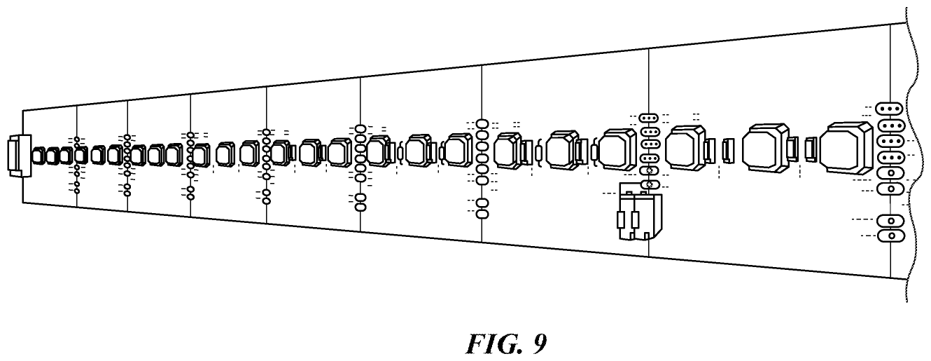

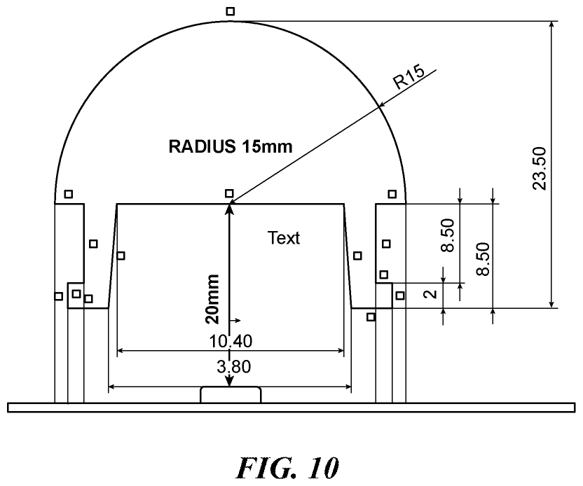

An illumination module can be constructed from an array of LED chips. The array of LED chips can be connected to a customized printed circuit board (PCB). FIG. 9 shows a photograph of the LED chips affixed serially to the PCB along a longitudinal axis, prior to the placement of the collimating lenses. The LED chips each can have 3 different wavelengths embedded in every single chip: UV (390 nm), IR (940 nm) and white light (4000-4500 K), and the PCB can be designed for common power line share. The PCB can also have lines and connectors for calibration lasers that aid in controlling the positioning of the illumination module, each one being separated by a predefined distance (e.g. 27.5 cm) —there are N number of connectors, N being the number of camera sensors coupled with the illumination module to create a material sensing system. Between each sequence of 3 LED chips, there can be a cutting line with metalized holes and the termination of the board is with a connector to drive both the LEDs and the lasers. The LED chips can be centered at the PCB, to ensure maximum light output and brightness uniformity after the acrylic lens that collimates the light. In addition, a customized acrylic lens that collimates the light on the fabric to a narrower band can be used for each LED chip, making the brightness more uniform along with the vertical axis of the fabric images, which can play a crucial role for artificial intelligence (AI) algorithms (quality assurance or defect detection) to be more efficient. In order to achieve the uniform brightness in the images, the acrylic lens can be of semi-circular shape with a predefined radius (e.g. 15 mm radius), with refractive index in the range of 1.48-1.50 (in the visible light spectrum). FIG. 10 depicts a schematic of the positioning of an acrylic lens relative to the light-emitting chip for the fabricated illumination module. A summary of some of the properties of the illumination module is displayed in Tables I-III below.

In some embodiments, the chips can be spaced apart in a parallel configuration. In some embodiments, the LED chips can be placed in a staggered, patterned, or offset configuration relative to a longitudinal axis. The offset of each LED chip relative to the longitudinal axis may be defined as the distance of an orthogonal line from the longitudinal axis to the center of the LED chip.

In some embodiments, the illumination module can comprise 90 LED chips per meter. This number can increase if the modules are placed directly adjacent to each other. The illumination module also featured a cutting line at each 3 chips sequence for lower probability of brightness errors due to electric tolerancing. The acrylic lens can be used to collimate the light in the fabric and produce uniform brightness along with the vertical axis of the fabric image, with the following requirements: Semi-circular shape, radius: 15 mm, refractive index: 1.48-1.50, and distance between top surface of LED chip to lens: 20 mm. The LED PCB and mechanical structure can be bi-directional, to allow power to be supplied to the PCB from both ends.

TABLE I
Electrical Properties of Illumination Module

| | |
|---|---|
| Working voltage | 8-52 VDC (flash only from 20 VDC up) |
| LEDs in series | 3 |
| Forward voltage | IR: 1.8 V |
| | WHITE: 3.1 V |
| | UV: 3.1 V |
| Resistors | IR: 99 Ohm |
| | WHITE: 81 Ohm |
| | UV: 81 Ohm |

TABLE II
Dimensional Properties of Illumination Module

| | |
|---|---|
| Width | Current: 27.9 mm. Can be made shorter |
| | but it is wise to keep the ground lines |
| | wide (with high clearance). |
| Length | Each camera sensor requires 30 cm of |
| | illuminated fabric. |

TABLE III
Life Cycle Estimates for Illumination Module

| | |
|---|---|
| Life cycle | 75,686,400 cycles; 2800 hr |

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1. An illumination system comprising:
one or more light sources configured to emit light; and
an optical element in optical communication with said one or more light sources and a material sheet,
wherein said optical element is configured to direct said light onto said material sheet to provide illumination along one or more axes of said material sheet, which one or more axes are associated with one or more directions in which said material sheet is produced, and wherein said illumination is useable to illuminate a target region of said material sheet to enable detection of one or more defects or to ensure quality control during a production or a processing of said material sheet.

2. The system of claim 1, wherein said optical element comprises one or more light organizing elements.

3. The system of claim 2, wherein said one or more light organizing elements comprises a direction-altering element selected from the group consisting of a collimating lens, a focusing lens, a focusing mirror, a defocusing lens, a defocusing mirror, a planar mirror, a parabolic mirror, a polygon rotating mirror, and a polarizing lens.

4. The system of claim 2, wherein said one or more light organizing elements comprises an intensity-altering element selected from the group consisting of a filtering lens, a beam splitter, a dichroic mirror, an iris, an aperture, a semi-transparent material, an attenuator, a patterned attenuator, and an opening.

5. The system of claim 1, wherein said one or more light sources comprises one or more light emitting diodes (LEDs).

6. The system of claim 5, wherein said one or more LEDs comprises an array of LEDs that are spaced apart along a longitudinal axis.

7. The system of claim 1, wherein said one or more light sources are configured to emit one or more beams having a wavelength from about 10 nanometers to about 1200 nanometers.

8. The system of claim 1, wherein said one or more axes comprises a predefined axis that is in a vertical direction along which said material sheet is produced.

9. The system of claim 8, wherein an optical axis of said light is transverse to said predefined axis of material sheet.

10. The system of claim 3, wherein said collimating lens has a radius of at least about five millimeters.

11. The system of claim 1, wherein said optical element is spaced apart from said one or more light sources by a gap.

12. The system of claim 11, wherein said gap is at least one millimeter.

13. The system of claim 1, wherein said optical element comprises a transparent plastic, a translucent plastic, a transparent glass, a translucent glass, a reflective metal, or a reflective coating.

14. The system of claim 1, wherein said illumination unit is configured to direct said light at one or more angles relative to a plane defined by said target region.

15. The system of claim 14, wherein said one or more angles ranges from about 1 degree to about 360 degrees.

16. The system of claim 1, wherein said illumination is configured to produce substantially uniform brightness along said one or more axes of said material sheet.

17. The system of claim 1, wherein said material sheet comprises a web, a fabric, a sheet, a textile, paper, a woven material, a non-woven material, a metal, a plastic, a composite, or a film.

18. The system of claim 1, wherein said material sheet is provided in, fabricated, or processed using a material fabrication and processing machine.

19. The system of claim 18, wherein said material fabrication and processing machine comprises a knitting machine selected from the group consisting of a circular knitting machine, a warp knitting machine, or a flat knitting machine.

20. The system of claim 18, wherein said material fabrication and processing machine comprises a weaving machine.

21. The system of claim 18, wherein said material fabrication and processing machine comprises a roll-to-roll processing machine.
